(19) United States
(12) Patent Application Publication
(10) Pub. No.: US 2004/0216672 A1
(43) Pub. Date: Nov. 4, 2004

(54) Processing apparatus and processing method

(76) Inventors: Katsumi Ishii, Kanagawa (JP); Nobuaki Takahashi, Tokyo (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/480,120

(22) PCT Filed: Jul. 11, 2002
(86) PCT No.: PCT/JP02/07064

(30) Foreign Application Priority Data
Jul. 25, 2001 (JP) 2001-224163
Jul. 25, 2001 (JP) 2001-224520
Jul. 25, 2001 (JP) 2001-224020
Jul. 25, 2001 (JP) 2001-224055

(51) Int. Cl. C23C 16/00

(52) U.S. Cl. 118/719; 118/724

(57) ABSTRACT

A plurality of semiconductor wafers (W) is housed inside cassettes (CR) of a cassette station (10). In a processing section (18), a plurality of processing chambers (54) is provided in multi-stages. A multi-staged substrate disposition section (14) for temporarily loading a plurality of semiconductor wafers disposed in a multi-staged state is provided between the cassette station (10) and the processing section (18). A loader/unloader section (12) transports semiconductor wafers one by one between the cassette station (10) and the multi-staged substrate disposition section (14). A transfer module (16) simultaneously transports a plurality of semiconductor wafers supported in a multi-staged state between the multi-staged substrate arrangement section (14) and the processing section (18).

### TECHNICAL FIELD

The present invention relates to a processing apparatus used for a process in manufacturing a semiconductor device, an LCD (Liquid Crystal Display) or the like, and more particularly, to a processing apparatus for performing a prescribed process to a substrate (a semiconductor wafer, an LCD substrate or the like) by using a prescribed gas inside a hermetically sealable processing chamber.

### BACKGROUND ART

In a processing apparatus used for a process in manufacturing a semiconductor device, an LCD (Liquid Crystal Display) or the like, a vacuum chamber such as a load-lock chamber or an inert gas chamber is provided in the front and back of a processing chamber, or either one of the front or back of a processing chamber. This allows a substrate to be transported into or out of the processing chamber without having to expose the processing chamber to the atmosphere. Particularly, with a multi-chamber processing type, plural processing chambers are disposed at the periphery of a hermetically sealable transport chamber, and substrates are randomly transported to and from each of the processing chambers via the transport chamber.

Typically, in the multi-chamber processing type, one of a plurality of chambers is employed as a cooling chamber, and a processed substrate, after being cooled to a prescribed temperature in the cooling chamber, is transported via the transport chamber to a load-lock chamber or a cassette station in which a cassette (substrate transport container) is received or disposed.

Further, an apparatus structure having a plurality of processing chambers, being disposed as multiple-stages, for simultaneously performing single wafer processing to plural substrates is known, in which plural substrates are transported in and out of the processing chambers simultaneously or in parallel. With this conventional type of processing apparatus, the plural substrates are transported, in parallel, between cassettes and the processing chambers in a manner such that the plural process substrates are placed in multiple stages on a transport arm.

In the foregoing conventional structure where plural substrates are simultaneously transported, in parallel from beginning to end, between the cassettes and the processing chambers, the plural substrates are always required to be inserted into or extracted from the cassettes at a side toward the load-lock chamber or the cassette station at a substrate housing location interval which is constant. This, therefore, causes a problem of restricting the degree of freedom from the aspect of transporting the substrates in and out of the cassettes or managing the housing of the substrates. In addition, since the said apparatus is a type where processed substrates are returned to the cassette after being cooled to a prescribed temperature, e.g. normal temperature, in a particular cooling chamber dedicated to cooling, the apparatus generates additional costs and foot print for the cooling chamber. Furthermore, owing to the complicated procedure of transporting the substrates in and out of the cooling chamber, said apparatus has a problem of a reduced throughput thereof.

Furthermore, in the process of manufacturing a semiconductor device, an LCD or the like, thermal processing is employed in various stages, for example, oxidation, diffusion, or hot-wall CVD. As current design rules become finer from 0.2 μm to 0.1 μm, and as the diameter for a semiconductor wafer grows larger from 200 mm to 300 mm, the need for developing a high temperature rapid thermal processing apparatus, which is compatible with a technology for forming a large area ultra thin film, is growing.

To be more precise, in doping by thermal diffusion doping or in forming an ultra thin film such as a gate oxide or a capacitor insulator, thermal processing is required to be executed rapidly, that is, in a short time, for reducing thermal budget (thermal history). Furthermore, in a PN junction, film deterioration during junction or creation of defective crystals needs to be prevented in order to form a shallow PN junction plane and reduce resistance or accomplish PN junction at a surface having a given shape. In order to do so, thermal diffusion processing is required to be executed at high temperature and thus at a rapid speed or in a short time.

Furthermore, in forming LOCOS oxide, expansion of compression stress of adjacent LOCOS oxide, which results from an interactive effect of a heat cycle, is liable to cause, for example, changes in surface potential, leaks of electric current, or deterioration in the property for withstanding pressure. Accordingly, it is necessary to reduce the heat cycle by rapid thermal processing.

In the current situation where the diameter of semiconductor wafers is increasing from 200 mm to 300 mm, slips, distortions, or bows, which are liable to be created upon the semiconductor wafers, need to be prevented or reduced. In order to do so, it is necessary to reduce the temperature difference between the center portion of the semiconductor wafer and the peripheral portion of the semiconductor wafer and thus execute rapid thermal processing uniformly.

A conventional thermal processing apparatus which is structured to be compatible with large diameter wafers is shown in FIG. 18. The thermal processing apparatus, for example, has a flat reaction tube 102 received in a relatively horizontal manner inside a hexagonal housing 100. Planar shaped resistance heating portions 104 and 106, which are disposed above and below the reaction tube 102 in a manner facing each other, are divided into three zones in a lengthwise direction or in a longitudinal direction (X direction) of the reaction tube 102, that is, a front zone (104a, 106a), a middle zone (104b, 106b), and a rear zone (104c, 106c).

Among the three zones, the middle zone (104b, 106b) is set to cover substantially the entire area of a semiconductor wafer W disposed on a substrate support portion 108 inside the reaction tube 102, and the front zone (104a, 106a) and rear zone (104b, 106b) are defined to cover the peripheral area at the front and back of the semiconductor wafer W.

In the front zone (104a, 106a) and rear zone (104c, 106c), numerous coiled resistance heating elements 110, each having a constant lead extending across their entire length, are provided laying across in the X direction as shown in FIG. 19A. Meanwhile, in the middle zone (104b, 106b), numerous coiled resistance heating elements 112, each having a densely arranged lead at both end portions thereof and a sparsely arranged lead at the middle portion thereof, are provided laying across in the X direction as shown in FIG. 19B. Inside each of the zones, the resistance heating elements 110 and 112 are electrically connected in series. Between different zones, the resistance heating elements 110 and 112 are electrically connected separately or in parallel.

Each of the zones (104a, 106a), (104b, 106b), and (104c, 106c) is electrically controlled by a heater circuit (not illustrated). If heat of uniform strength were to be emitted from the entire planes of the resistance heating portions 104 and 106 to the semiconductor wafer W, temperature at the peripheral portion of the semiconductor wafer W would tend to be relatively lower than the center portion thereof. As described above, in the thermal processing apparatus, the resistance heating portions 104, 106 are divided into the three zones (104a, 106a), (104b, 106b), and (104c, 106c), and the leads of the resistance heating elements 110 in the front zone (104a, 106a) and the rear zone (104c, 106c) are relatively arranged more densely (formed with a smaller pitch) compared to the leads of the resistance heating elements 112 in the middle zone (104b, 106b), to thereby provide a uniform heating temperature in the longitudinal direction (X direction) of the reaction tube 102. Furthermore, in the leads of the resistance heating elements 112 in the middle zone (104b, 106b), the end portions are provided with a density that is relatively higher than that of the center portion, to thereby provide a uniform heating temperature in the lateral width direction (Y direction).

It is to be noted that a heat spreading plate or a heat diffusing plate 114 formed from high purity silicon carbide (SiC), for example, may be disposed between the resistance heating portions 104, 106 and the reaction tube 102. Further, a gas tube 116 is connected to a rear surface of the reaction tube 102 for taking in process gas and discharging exhaust gas.

Nevertheless, the foregoing resistance heating type, having the resistance heating elements 112 formed with leads with a sparsely arranged portion and a densely arranged portion, increases the cost for manufacturing the resistance heating elements 112, and makes it difficult to simultaneously adjust heat uniformly in both the longitudinal direction (direction X) and the lateral direction (direction Y). In addition, it is also difficult to distribute heat uniformly since the optimum ratio of the denseness/sparseness for the leads changes depending on the heating temperature.

FIG. 20 shows a structure of a substrate retaining portion of a conventional substrate transport apparatus used for a rapid thermal processing apparatus. The substrate retaining portion 100 has a pair of arm portions 102, 102, extended in parallel and suitably spaced from each other. The substrate retaining portion 100 transports a substrate (e.g. semiconductor wafer W) by horizontally placing the substrate on plural (e.g. three) projecting support portions 104, 104, 104 being suitably spaced from each other and disposed on the top surface of the arm portions 102, 102.

In the above described high temperature rapid thermal processing, the substrate transport apparatus quickly extracts the substrate from the furnace immediately after the processing, and transports the substrate to a cooling chamber or a stage that is situated outside of the furnace. With the conventional substrate transport apparatus in this situation, the substrate (semiconductor wafer W), still being in a high temperature state (e.g. 1000° C.), is placed on the projecting support portions 104 of the substrate retaining portion 100, and, therefore, cooling of the substrate (semiconductor wafer W) is localized or concentrated at a portion contacting the projecting support portions 104. This creates a large difference in temperature on the surface of the substrate, and results in generation of slip. Generation of slip causes problems such as plastic deformation (bowing) of the substrate, and errors in a photolithography procedure.

### DISCLOSURE OF INVENTION

It is a general object of the present invention to provide an improved and useful processing apparatus and processing method in which the above-mentioned problems are eliminated.

A more specific object of the present invention is to provide a processing apparatus and a processing method that can increase flexibility in substrate arrangement management and efficiency in transportation, and improve throughput for a single wafer type that simultaneously performs a prescribed process on plural substrates inside plural processing chambers being disposed as multi-stages.

Another object of the present invention is to provide a processing apparatus and a processing method that can lower cost, reduce foot print, and increase throughput without requiring a dedicated chamber or stage for cooling a processed substrate to a predetermined temperature.

Another object of the present invention is to provide a processing apparatus and a processing method that allow rapid thermal processing to be executed efficiently in a shorter time.

Another further object of the present invention is to provide a thermal processing apparatus that has a simple low cost structure for allowing a substrate to be heated with a uniform temperature distribution.

Another object of the present invention is to provide a thermal processing apparatus that can rapidly heat or thermally process an entire targeted surface with a highly precise uniform temperature, even for a large-sized substrate.

Another further object of the present invention is to provide a substrate transport apparatus that can prevent defects, such as slip, from being created upon a substrate that has just been subjected to thermal processing, especially, high temperature rapid thermal processing.

Another object of the present invention is to provide a processing method that can prevent or withhold defects such as slip from being created upon a substrate, and execute thermal processing, especially, high temperature rapid thermal processing.

In order to achieve the above-mentioned objects, there is provided according to one aspect of the present invention a processing apparatus having: a station for housing a plurality of substrates in a substrate transport container; a processing section at which a plurality of processing chambers are provided in multi-stages for applying a prescribed process to the respective substrates inside a hermetically sealable chamber by using a prescribed process gas; a multi-staged substrate disposition section for temporarily loading the substrates being disposed in a plural multi-staged state, between the station and the processing portion; a first transport part for transporting the substrates one by one between the station and the multi-staged substrate disposition portion; and a second transport part for transporting a plurality of substrates, being supported in the multi-staged state, simultaneously between the multi-staged substrate disposition portion and the processing portion.

Thus structured, the first transport part can choose a random substrate housing location inside a random substrate transport container as a target for access since substrates are transported to and from the station one substrate at a time. Accordingly, a wafer can be quickly and accurately extracted and inserted even where the intervals between wafer housing locations inside the substrate transport container are limited. Further, the first transport part can access each of the stages of the substrate disposition portion and transport substrates to and from at separate timings flexibly, given that the first transport part can also transport substrates to and from the multi-staged substrate disposition section one substrate at a time. Meanwhile, simultaneous single wafer processing can be executed upon plural substrates efficiently and accurately since the second transport part supports and transports unprocessed or processed substrates between the multi-staged substrate disposition section and the processing section.

A preferred embodiment of the processing apparatus according to the present invention may be a thermal processing apparatus provided with a thermal processing part for thermally processing the substrates inside each of the processing chambers of the processing section; further, it may also be preferable to provide a rapid thermal processing apparatus having the thermal processing part structured as a rapid thermal processing part.

As a preferred embodiment where structured as the rapid thermal processing apparatus, the rapid thermal processing part may have a heat radiation part for applying radiant heat, more or less perpendicularly, to the entire surface of the substrate, and the heat radiation part may have a resistance heating member that generates Joule heat. Further, a temperature control part may preferably be provided to the structure so as to maintain a substantially constant heating temperature for the substrate during a period where the substrate is transported in and out of each processing chamber.

Further, an alignment part, serving to arrange the substrate toward a prescribed direction, may be provided to the structure at a location accessible by the first transport part. In this case, the alignment part may be structured to arrange the substrates one by one.

A preferred embodiment of the multi-staged substrate disposition section in the processing apparatus according to the present invention may be structured having a plurality of load-lock chambers receiving the substrates one by one. In this case, the second transport part may be provided inside the transport chamber that is connected to all of the load-lock chambers of the multi-staged substrate disposition section, and also connected to all of the processing chambers of the processing section.

More preferably, the multi-staged substrate disposition section may include: a multi-staged unprocessed substrate disposition portion for temporarily loading a plurality of the substrates being disposed in a multi-staged state, prior to being processed at the processing section; and a multi-staged processed substrate disposition portion for temporarily loading a plurality of the substrates being disposed in a multi-staged state, subsequent to being processed at the processing section. Thus structured, a procedure of transporting unprocessed wafers and transporting processed wafers can be executed in parallel or simultaneously, thereby enabling increase of throughput.

Further, it may be preferred that the multi-staged processed substrate disposition portion have a cooling mechanism for cooling the substrates to a prescribed temperature. Thus structured, processed substrates can be cooled to a prescribed temperature while being loaded on the multi-staged processed substrate disposition portion; therefore, no dedicated cooling chamber requiring a particular occupation space shall be necessary.

Further, in the processing apparatus according to the present invention, the thermal processing part may have: a reaction tube in which the substrate is received and disposed at a prescribed position; a first resistance heating portion being structured as a planar shape, and facing substantially in parallel to the substrate received in the reaction tube; and a second resistance heating portion being structured as a planar shape at a periphery of the substrate received in the reaction tube, and perpendicularly intersecting with the first resistance heating portion.

In the structure, with only the radiant heat from the first resistance heating portion, the temperature at the end portion of the substrate in a certain direction tends to become lower than the center portion thereof; however, uneven temperature distribution in the said direction can be effectively adjusted by radiant heat from the second resistance heating portion.

In the processing apparatus according to the present invention, it may be preferable to provide the first resistance heating portion at the front and back surfaces of the substrate. From the aspect of size and function of the apparatus, it may be preferable to provide the second resistance heating portion at the left and right sides in a lateral direction perpendicularly intersecting with a longitudinal direction where the substrate is transported to and from the reaction chamber.

In order to obtain a more uniform temperature distribution, the first resistance heating portion may preferably be divided into a plurality of zones, and perform resistance heating by being electrically controlled independently in each of the zones. In the division of the zones, the first resistance heating portion may preferably be divided in the longitudinal direction where the substrate is transported to and from the reaction chamber, into a first zone covering substantially the entire area or large portion of the substrate, and second and third zones disposed at the front and rear of the first zone. Thus structured, unevenness of temperature distribution in the longitudinal direction can be adjusted.

In order to adjust temperature distribution more accurately by electrical control with the resistance heating portion according to the present invention, the second resistance heating portion may, preferably, perform resistance heating by being electrically controlled independently from each zone of the first resistance heating portion; or the second resistance heating portion may be disposed at the left and right of the substrate as a pair and perform resistance heating by being electrically controlled independently from each other.

In order to simplify the structure of the resistance heating portion, coiled resistance heating elements, having a relatively constant lead, may be distributed in a planar manner over the entire length of each resistance heating portion. In the first resistance heating portion, it may be preferable to provide respective resistance heating elements in a manner extending in the lateral direction perpendicularly intersecting the longitudinal direction in which the substrate is inserted or extracted to and from the reaction tube, and it may be preferable to lay a plurality of resistance heating elements in the longitudinal direction. In the second resistance heating portion, it may be preferable to provide respective resistance heating elements in a manner extending in the longitudinal direction in which the substrate is inserted or extracted to and from the reaction tube, and it may be preferable to lay a plurality of resistance heating elements in the vertical direction perpendicularly intersecting the longitudinal direction.

Further, in order to increase the accuracy of electrical control or temperature control of the resistance heating portion, a temperature detection part may be provided in the resistance heating portion or each zone, at which resistance heating is performed by independent electrical control, for feeding back heating temperature to each electric control.

Further, in order to increase heating efficiency, it may be preferable to surround the outer side of the first and second resistance heating portions with a heat insulation member. Further, a heat spreading member or a heat diffusing member may be provided between the first resistance heating portion and/or the second resistance heating portion and the reaction tube.

Further, the first and second resistance heating portions may be heating members using a heater enclosing a carbon fiber, which is braided into a net, inside a sealing member. The sealing member may be formed of quartz glass or alumina.

Further, in the processing apparatus according to the present invention, the second transport part may have: a pair of arm portions being spaced with an interval larger than the width of the substrate, and facing substantially horizontal to each other; and a plurality of retaining portions being provided to the pair of arm portions at prescribed intervals, and being in contact with a peripheral portion of the substrate for retaining the substrate.

Thus structured, the substrate, being placed at a back side of its peripheral portion, is retained by both arm portions in a substantially horizontal manner. Thereby, even where contact with the retaining portion creates some kind of defect upon the substrate, the creation of the defect can be restricted within the peripheral portion of the substrate. Therefore, yield decrease can be prevented.

The retaining portion may, preferably, be structured extending from the arm portion to an inner side in a width direction. Thus structured, an arm structure formed as thin as possible can be obtained. Further, the retaining portion may be formed as a claw-like member protruding from the arm portion to the inner side in the width direction, and more preferably, may be formed as a planar piece attached to the arm portion where a plane surface thereof is perpendicularly disposed. Thus structured, the area contacting the substrate can be reduced while still obtaining the strength of the retaining portion.

The retaining portion has a top surface thereof contacting the back side of the substrate. A preferable top surface structure of the retaining portion may be a structure sloped downwards from a proximal end portion toward the arm portion to a distal end portion, and more preferably, the downward sloped surface may have a protruding planar roundness. Thus structured, linear contact with the substrate can be achieved harmoniously, thereby making it more difficult for defects such as slips to be created.

Although the number of retaining portions can be chosen discretionarily, it is preferable to provide two retaining portions to each arm from the aspect of cost-effectiveness. The material of the retaining portion may preferably be a material having thermal resistance, for example, quartz.

According to another aspect of the present invention, there is provided a processing method including: a first step placing a plurality of unprocessed substrates in a prescribed station; a second step separately transporting a plurality of unprocessed substrates from the station to a plurality of substrate placement areas being set in multi-stages; a third step temporarily loading a plurality of unprocessed substrates on the multi-staged substrate placement area; a fourth step simultaneously transporting a plurality of unprocessed substrates from the multi-staged substrate placement area to a plurality of chambers being disposed in multi-stages; a fifth step simultaneously applying a prescribed process to the plurality of substrates inside each of the plurality of chambers by using a prescribed process gas; a sixth step simultaneously extracting and transporting a plurality of processed substrates from the plurality of chambers to the multi-staged substrate placement area; a seventh step temporarily loading a plurality of processed substrates on the multi-staged substrate placement area; and an eighth step separately transporting a plurality of processed substrates from the multi-staged substrate placement area to the station.

In the processing method according to the present invention, the substrates may, preferably, be simultaneously thermally processed in the plurality of chambers in the fifth step. It is more preferable to perform rapid thermal processing on the substrate in a short time. Further, the sixth step may be a step where the heating temperature for the substrate inside the processing chamber is maintained at a substantially constant temperature during a period from the inserting of the substrate into each chamber to the extracting of the substrate.

Furthermore, as a preferable embodiment, a plurality of sets of the multi-staged substrate placement area may be provided, wherein one set of unprocessed substrates is loaded on a first set of the multi-staged substrate placement area while another set of processed substrates is loaded on a second set of the multi-staged substrate placement area. In this case, by cooling plural processed substrates to a prescribed temperature at the second set of the multi-staged substrate placement area, the second set multi-staged substrate placement area can also be used as a cooling chamber or stage.

According to another aspect of the present invention, there is provided a thermal processing method including: a first step keeping the inside of a reaction tube at a predetermined temperature; a second step transporting a substrate into the reaction tube at the predetermined temperature by using a substrate transport apparatus which retains and transports a substrate in a substantially horizontal state, the substrate transport apparatus having a pair of arm portions being spaced with an interval greater than the width of the substrate, and facing substantially horizontally to each other, and a plurality of retaining portions being provided to the pair of arm portions at prescribed intervals, and being in contact with a peripheral portion of the substrate for retaining the substrate; a third step applying a prescribed thermal process to a targeted process surface of the substrate by supplying a prescribed process gas to the reaction tube while exhausting the inside of the reaction tube; a fourth step withdrawing the substrate out from the reaction tube with the substrate transport apparatus after a predetermined process time has elapsed; and a fifth step cooling the withdrawn substrate to a prescribed temperature at a cooling portion set outside of the reaction tube. In the thermal processing method, the inside of the reaction tube may preferably be maintained at the predetermined temperature from beginning to end in the third step.

According to another aspect of the present invention, there is provided a thermal processing apparatus including: a reaction tube in which a substrate is received and disposed at a prescribed position; a first resistance heating portion being structured as a planar shape, and facing substantially in parallel to the substrate received in the reaction tube; a second resistance heating portion being structured as a planar shape at a periphery of the substrate installed in the reaction tube, and perpendicularly intersecting with the first resistance heating portion; a heat spreading member being provided between the reaction tube and the first/second resistance heating portions so that the heat created in the first/second resistance heating portions is uniformly spread inside the reaction tube; and a heat insulating member being provided to surround the first/second resistance heating portions. In the thermal processing apparatus, it is preferable to provide a temperature detection unit for feeding back the temperature in each zone of the first/second resistance heating portions to an electric control for each zone.

Further, according to another aspect of the present invention, there is provided a substrate transport apparatus which retains and transports a substrate in a substantially horizontal state, the substrate transport apparatus including: a pair of arm portions being spaced with an interval greater than the width of the substrate, and facing substantially horizontally to each other, and a plurality of retaining portions being provided to the pair of arm portions at prescribed intervals, and being in contact with a peripheral portion of the substrate for retaining the substrate.

Other objects, features and advantages of the present invention will become more apparent from the following detailed description when read in conjunction with the accompanying drawings.

### BRIEF DESCRIPTION OF DRAWINGS

FIG. 1 is a partial cross-sectional view showing an entire structure of a processing apparatus according to one embodiment of the present invention;

FIG. 2 is a plan view showing an entire structure of a processing apparatus according to an embodiment;

FIG. 3 is a plan view showing a structure of pincers of a transport arm of a transfer module according to an embodiment;

FIG. 4 is a partial perspective view showing a structure of an essential portion of pincers of a transport arm of a transfer module according to an embodiment;

FIG. 5 is an enlarged side view showing a structure of a claw portion of pincers of a transport arm according to an embodiment;

FIG. 6 is a schematic exploded perspective view showing a structure of a resistance heating device in a processing chamber according to an embodiment;

FIG. 7 is a schematic perspective view showing a structure (assembly) of a resistance heating device according to an embodiment;

FIG. 8 is a cross-sectional view showing a detailed structure of a resistance heating device according to an embodiment;

FIG. 9 is a cross-sectional view showing a detailed structure of a resistance heating device according to an embodiment;

FIG. 10 is a view showing a circuit structure of a charge control portion of a resistance heating device according to an embodiment;

FIG. 11 is a plan view showing a structure of a reaction tube of a processing chamber according to an embodiment;

FIG. 12 is a cross-sectional view showing a structure of a reaction tube according to an embodiment;

FIG. 13 is a rear view showing a structure of a reaction tube according to an embodiment;

FIG. 14 is a cross-sectional view showing a structure of a reaction tube according to an embodiment;

FIG. 15 is a cross-sectional view showing a structure of a reaction tube according to a modified embodiment;

FIG. 16 is a cross-sectional view showing a structure of a gate valve according to an embodiment;

FIG. 17 is a cross-sectional view showing a structure of a portion of a gate valve according to an embodiment;

FIG. 18 is a cross-sectional view showing a structure of a conventional thermal processing apparatus;

FIGS. 19A and 19B are side views of a resistance heating elements used for a conventional thermal processing apparatus; and

FIG. 20 is a plan view showing a structure of a substrate retaining portion of a conventional substrate transport apparatus.

### BEST MODE FOR CARRYING OUT THE INVENTION

A description of embodiments of the present invention is given below with reference to the drawings. It is to be noted that like components are denoted by like numerals throughout the drawings.

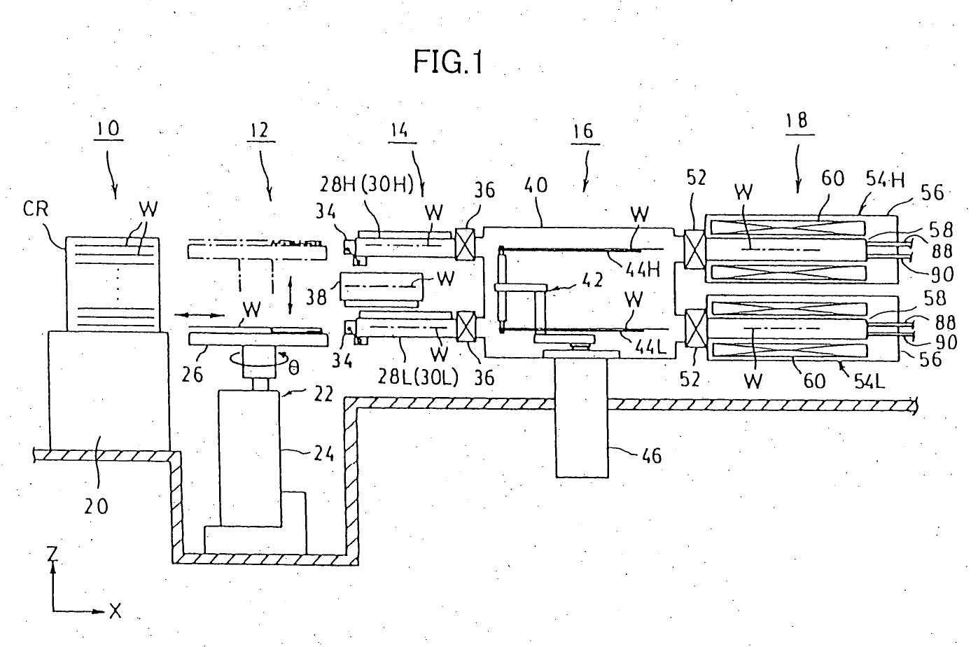

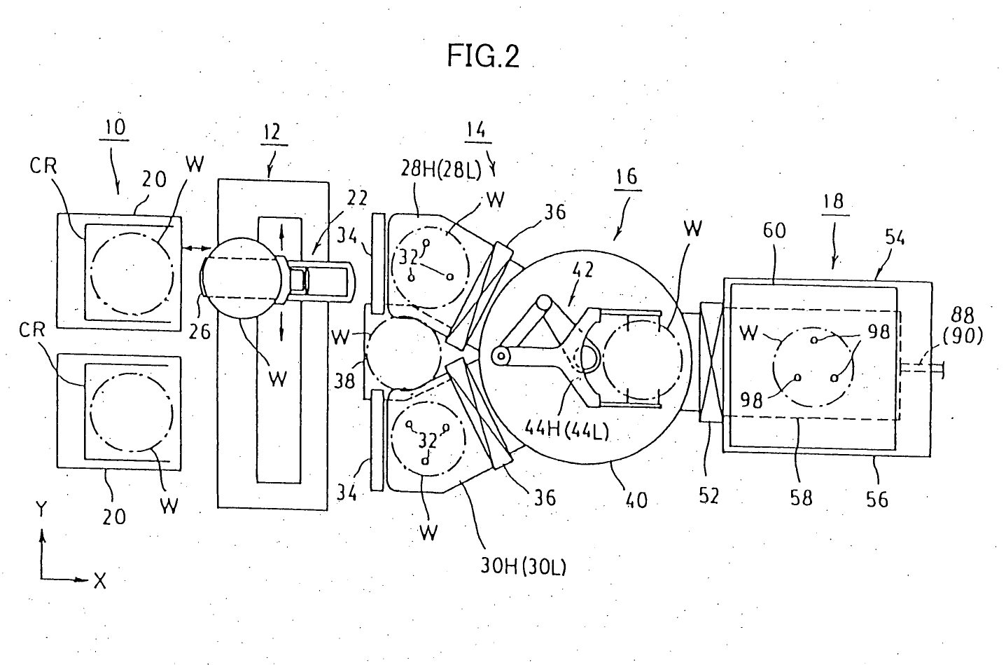

FIGS. 1 and 2 show an entire structure of a processing apparatus according to an embodiment of the present invention. The processing apparatus is a thermal processing apparatus performing thermal processing (e.g. oxidation, diffusion, annealing, thermal CVD (Chemical Vapor Deposition)) with a rapid thermal processing method in a process for manufacturing, for example, a semiconductor device, or an LCD.

The processing apparatus includes five sections composed of a cassette station 10, a loader/unloader portion 12, a load-lock module 14, a transfer module 16, and a process module 18.

The cassette station 10 is provided with one or a plurality of cassette stacking bases 20 which are aligned in a horizontal direction, for example, in direction Y. One cassette (or a carrier) CR is stacked on each cassette stacking base 20. The cassette CR is structured for receiving substrates (e.g. semiconductor wafer W), in a horizontal position, in a manner where the substrates are disposed as multi-stages in a vertical direction at prescribed intervals, thus allowing the substrates to be randomly transported in or out of an opening in a side surface. For example, an unattended transport vehicle (not shown) such as an AGV (Automatic Guided Vehicle) or an RGV (Rail Guided Vehicle) may access the cassette station 10, and then, the cassette CR receiving the semiconductor wafer W, which is not yet processed, may be set to a prescribed cassette stacking base 20; or the cassette CR receiving the semiconductor wafer W, which is processed, may be transported from a prescribed cassette stacking base 20.

The loader/unloader section 12 includes a wafer transport mechanism 22 for transporting the semiconductor wafer W one by one between cassette station 10 and the load-lock module 14. The wafer transport mechanism 22 includes: a transport member 24 capable of moving in a cassette alignment direction of the cassette station 10 (direction Y); and a transport arm 26 being placed on the transport member 24 and being capable of moving in direction Z, direction θ, and direction X. The transport arm 26 is able to access the front of a desired cassette CR at a desired height, and then extract a single semiconductor wafer W from the corresponding wafer housing location in the cassette CR, or insert a single semiconductor wafer W into a corresponding wafer housing location.

The load-lock module 14 has two sets of plural (for example, a pair) load-lock chambers (28H, 28L), (30H, 30L) which are disposed left and right, as multi-stages above one another in a vertical direction. More specifically, a pair of load-lock chambers 28H, 28L, vertically disposed as multi-stages and situated on the left side when viewed from the loader/unloader section 12, serves as a multi-staged unprocessed substrate disposition portion for temporarily loading unprocessed semiconductor wafers W thereon. Further, a pair of load-lock chambers 30H, 30L, vertically disposed as multi-stages and situated on the right side, serves as a multi-staged processed substrate disposition portion for temporarily loading processed semiconductor wafers W thereon. In this embodiment, the load-lock chambers 30H, 30L of the multi-staged processed substrate disposition portion also serve as cooling chambers or stages for cooling the processed semiconductor wafers W to a prescribed temperature.

A wafer placement portion formed of plural supporting pins (e.g. three pins) is provided inside each of the load-lock chambers 28H, 28L, 30H, 30L. Further, a vacuum pump (not shown) or an inert gas supply portion (not shown) is connected to each load-lock chamber, to thereby create a vacuum or an inert gas environment in the chamber. Furthermore, the load-lock chambers 30H, 30L of the multi-staged processed substrate disposition portion, also serving as a cooling chamber, may also be provided with a water or air type cooling mechanism (not shown).

In the load-lock chambers 28H, 28L of the multi-staged unprocessed substrate disposition portion, an opening with an open-close door 34 is provided to its side surface facing the loader/unloader section 12, to thereby form an entrance (wafer transport entrance). Further, an opening interposingly connects the transfer module 16 and the gate valve 36, to thereby form an exit (wafer transport exit). The wafer transport mechanism 22 of the loader/unloader section 12 transports unprocessed wafers W one by one into the load-lock chambers 28H, 28L in a separate timing.

In the load-lock chambers 30H, 30L of the multi-staged processed substrate disposition portion, an opening with an open-close door 34 is provided to its side surface facing the loader/unloader section 12, to thereby form an exit (wafer transport exit). Further, an opening interposingly connects the transfer module 16 and the gate valve 36, to thereby form an entrance (wafer transport entrance). The wafer transport mechanism 22 of the loader/unloader section 12 transports processed wafers W one by one out of the load-lock chambers 30H, 30L in a separate timing.

An alignment unit 38, which is accessible with the wafer transport mechanism 22 of the loader/unloader, section 12, is situated adjacent to the load-lock chambers 28H, 28L, 30H, 30L. An alignment mechanism (not shown) is provided inside the alignment unit 38 for directing a notch or an orientation flat of the semiconductor wafer W toward a prescribed direction.

The transfer module 16 includes a cylindrical transport chamber 40 having a closed top surface and a closed bottom surface. A transport arm 42, being rotatable and thus retractable or extendable, is disposed inside the transport chamber 40. The transport arm 42 has pincers 44H, 44L, being disposed in pairs or in two vertical stages, in which the pincers 44H, 44L horizontally move in parallel at a prescribed height. Two semiconductor wafers W are retained in two vertical stages by the pincers 44H, 44L and are simultaneously transported in parallel. A machine chamber 46, receiving a drive source for driving the transport arm 42, is disposed below the transport chamber 40.

Disposed on the side surface of the transport chamber 40 are: openings for connecting with the load-lock chambers 28H, 28L, 30H, 30L via the gate valves 36; and openings for connecting with the processing chambers 54H, 54L of the process module 18 (described below) via the gate valves 52.

It is preferable for the transport chamber 40 to have a hermetically sealable structure, and is also preferable to connect the transport chamber 40 with a vacuum pump (not shown) or an inert gas supply portion (not shown) for creating a vacuum or an inert gas environment in the chamber space.

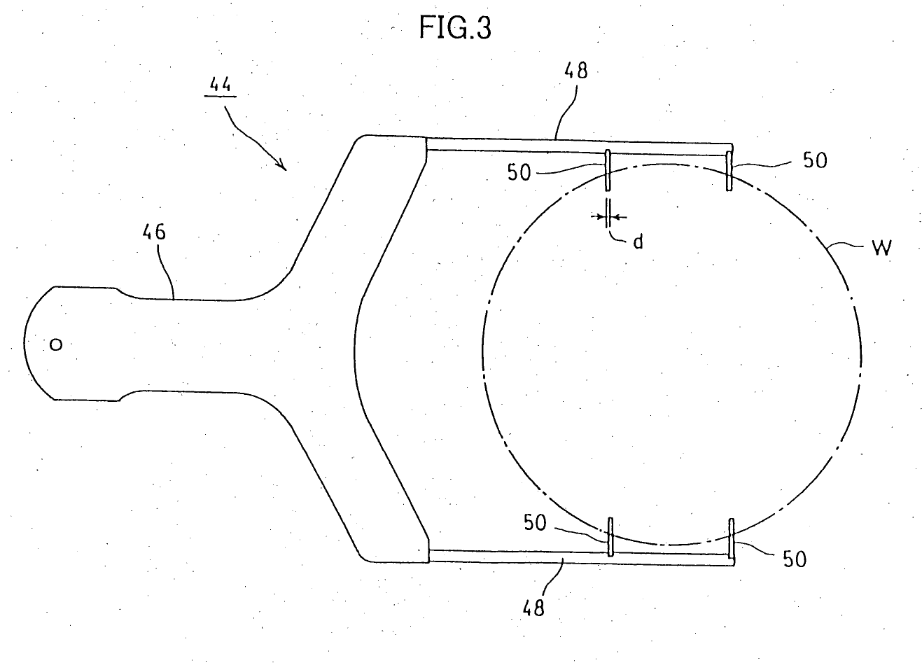

FIGS. 3, 4, and 5 show a structure of the pincers 44 (44H, 44L) of the transport arm 42 provided in the transport chamber 40. The pincers 44 includes: a Y shaped base portion 46 extending in a horizontal direction; a pair of tubular arm portions 48, 48 horizontally extending, in parallel, from a pair of distal end portions of the base portion 46; and a plurality of claw portions 50, arranged, in a prescribed interval, from a middle portion of both arm portions 48, 48 to a distal end portion of both arm portions 48, 48 in a manner protruding more or less horizontally for retaining a wafer. Each part of the pincers 44 (46, 48, 50) is formed from high heat resistant material such as quartz glass.

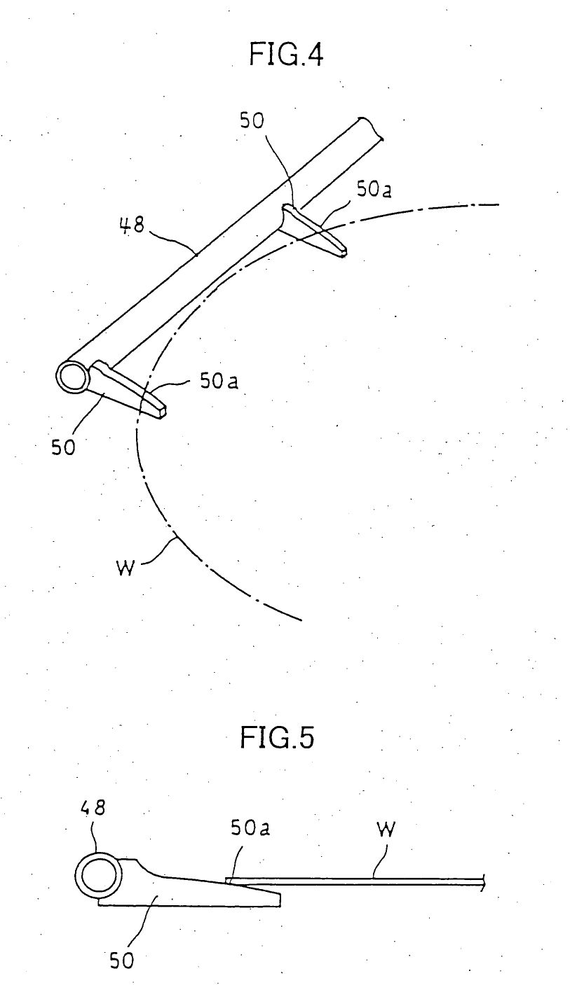

Each of the claw portions 50 is formed as a planar piece having a thickness of d (e.g. approximately 0.8 mm), and is welded to the arm portion 48 in a manner where a board surface thereof is disposed perpendicularly. A top surface of the claw portion 50, having a substantially protruding planar roundness, is sloped downward from a proximal end portion to a distal end portion. A contacting portion 50a is situated at a mid-section of the round-shaped sloped surface. As shown in FIGS. 4 and 5, a peripheral portion of the semiconductor wafer W is horizontally placed on the contact portion 50a of each of the claw portions 50 in a substantially linear contact manner.

The transfer arm 42 transfers the semiconductor wafer W by holding the semiconductor wafer W between both arm portions 48, 48 of the pincers 44. In this state, the semiconductor wafer W is in contact with the claw portions 50 at a wafer periphery portion (i.e. excluded peripheral area). Accordingly, creation of crystal defects, e.g. slip, may be prevented in a case where, for example, the semiconductor wafer W is transported out from the process module 18 (described below) immediately after being subjected to high temperature rapid thermal processing at 1000° C. or more.

In the process module 18, each processing chamber 54 (54H, 54L) is structured as a thermal processing portion for rapid heating. Each processing chamber 54 (54H, 54L) may, for example, have a box-type housing 56 shaped as a rectangular solid, in which the housing 56 has a reaction tube 58 and a resistance heating device 60 installed therein. The reaction tube 58 is formed from quartz.

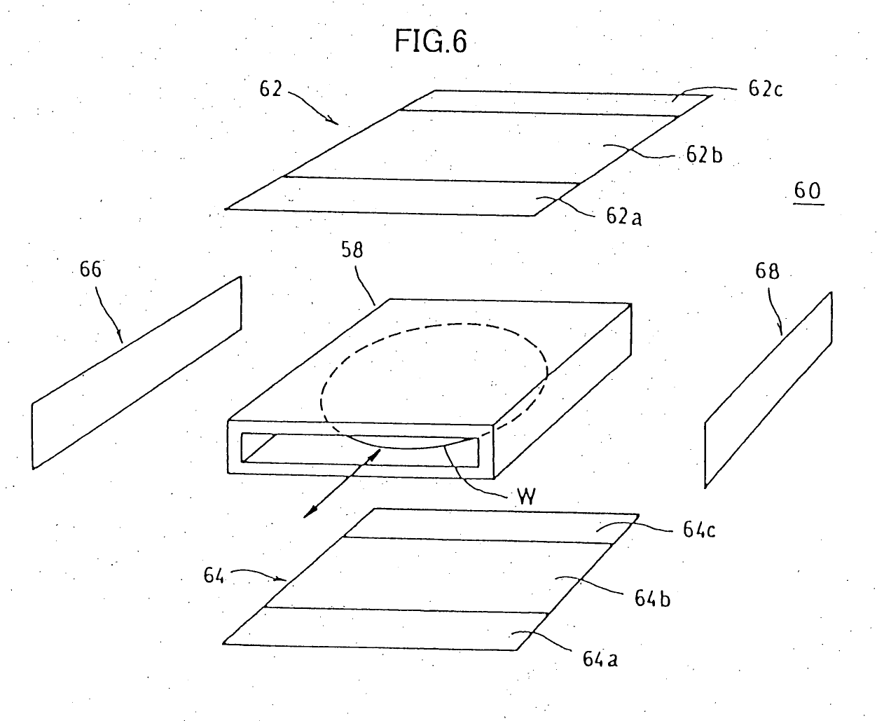

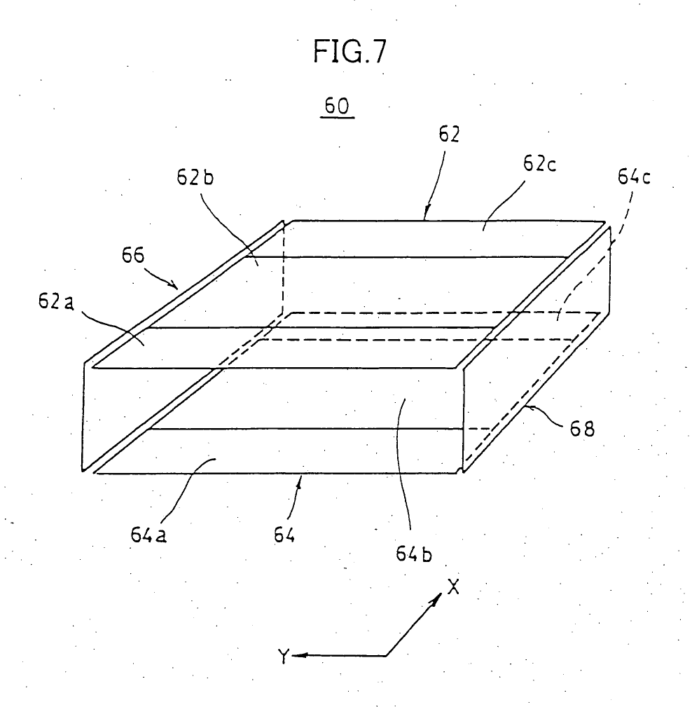

FIGS. 6 and 7 show a schematic structure of the resistance heating device 60 in the processing chamber 54. The resistance heating device 60 in this embodiment has a top surface resistance heating portion 62, a bottom surface resistance heating portion 64, a left surface resistance heating portion 66, and a right surface resistance heating portion 68, which are planar shaped, and are adjacently and oppositely situated at the top surface, the bottom surface, the left surface, and the right surface, respectively, of the reaction tube 58 having a flat and substantially hexahedral shape. Each of the planar resistance heating portions 62-68 generates radiant heat by Joule heat and heats the semiconductor wafer W inside the reaction tube 58. It is to be noted that, for example, a heat spreading plate or a heat diffusing plate (not shown) formed from high purity silicon carbide (SiC) may be provided in front of the heat radiating surface of each of the planar resistance heating portions 62-68.

The top surface resistance heating portion 62 and the bottom surface resistance heating portion 64, when viewed from the entrance side of the chamber, are respectively divided into a plurality of zones in a longitudinal direction (direction X), for example, front zone 62a, 64a, middle zone 62b, 64b, and rear zone 62c, 64c; thereby allowing each of the zones to be electrically controlled independently. Among the three zones, the middle zone 62b, 64b is set to cover substantially the entire area of the semiconductor wafer W received in the reaction tube 58, and the front zone 62a, 64a and the rear zone 62c, 64c are set to cover the front and rear portions of the semiconductor wafer W. The left surface resistance heating portion 66 and the right surface resistance heating portion 68 function as single side zones.

Thus structured, the middle zone 62b, 64b of the top surface resistance heating portion 62 and the bottom surface resistance heating portion 64 apply radiant heat, more or less vertically, to the entire surface of the semiconductor wafer W inside the reaction tube 58. Nevertheless, temperature at the peripheral portion of the semiconductor wafer W tends to be relatively lower than that of the center portion and the entire semiconductor wafer W may not be achieve a uniform temperature distribution in a case where merely the middle zone 62b, 64b is employed for heating.

In this embodiment, the peripheral portion of the wafer in the longitudinal direction (direction X) is reinforced with radiant heat from the front zone 62a, 64a and the rear zone 62c, 64c of the top surface resistance heating portion 62 and the bottom surface resistance heating portion 64. Further, the peripheral portion of the wafer in the lateral transverse direction (direction Y) is reinforced with radiant heat from the left surface resistance heating portion 66 and the right surface resistance heating portion 68. Accordingly, unevenness of temperature resulting from heating by merely the middle zone 62b, 64b can be effectively adjusted, and heat can be evenly distributed to the entire wafer.

Especially, the left surface resistance heating portion 66 and the right surface resistance heating portion 68 are provided on left and right sides, respectively, to serve as planar resistance heating portions that intersect perpendicularly with the wafer plane of the semiconductor wafer W. Accordingly, only minimal occupation space is required, a highly accurate and uniform temperature is obtained without having to increase the size of the processing chamber 54, and accommodation to increases in the diameter of semiconductor wafers is attained.

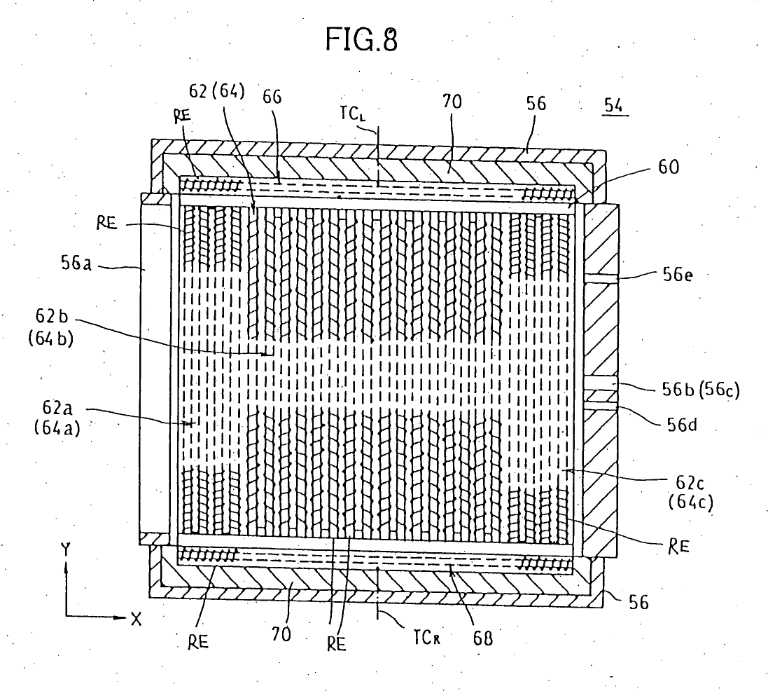

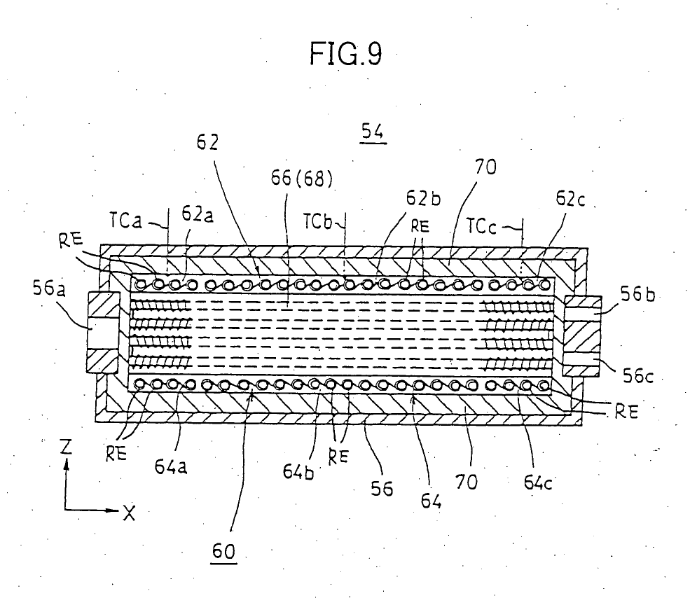

FIGS. 8 and 9 show a specific structure of the resistance heating device 60 according to one embodiment. In this embodiment, a heat insulation member 70 (formed of, for example, ceramic material) is disposed between the housing 56 (formed of, for example, stainless steel) and each of the respective planar resistance heating portions 62, 64, 66, 68 of the resistance heating device 60. Each planar resistance heating portion 62, 64, 66, 68 has numerous coiled resistance heating elements PE arranged on a surface thereof (in a two-dimensional direction). The resistance heating element PE is formed with, for example, a core rod (core) around which is wound, for example, a resistance heating wire formed of molybdenum disilicide (MoSi₂) or a resistance heating wire such as Kanthal (commercial name, an alloy wire of iron (Fe), chromium (Cr) and aluminum (Al)), in a uniform pitch or lead.

More specifically, in the top surface resistance heating portion 62 and the bottom surface resistance heating portion 64, resistance heating elements RE are provided in a manner extending in a lateral transverse direction (direction Y), and plural resistance heating elements RE are laid in a longitudinal direction (direction X). Further, in the left surface resistance heating portion 66 and the right surface resistance heating portion 68, resistance heating elements RE are provided in a manner extending in a longitudinal direction (direction X) from end to end of the top surface resistance portion 62 and the bottom surface resistance heating portion 64, and resistance heating elements RE are laid in a vertical direction (direction Z) in a manner filling the spaces between the top surface resistance heating portion 62 and the bottom surface resistance heating portion 64.

In each zone 62a, 62b, 62c, 64a, 64b, 64c, 66, and 68, all resistance heating elements RE may be electrically connected in series. Among different zones, resistance heating elements RE may, basically, be electrically separated or connected in parallel. Nevertheless, the front zone 62a, the middle zone 62b, and the rear zone 62c of the top surface resistance heating portion 62 may be connected in series with the oppositely disposed front zone 64a, the middle zone 64b, and the rear zone 64c of the bottom surface resistance heating portion 64. Further, the left surface resistance heating portion 66 and the right surface resistance heating portion 68, facing each other, may be connected in series to be subject to the same electrical control; alternatively, it may be preferable to connect both resistance heating portions (66, 68) separately or in parallel so as to electrically control each of them independently.

In order to feed back the heating temperature to a temperature control circuit, a temperature sensor, such as a thermo couple TC, is attached to each zone at which electrical control is performed independently. In this embodiment, thermo couples TCa, TCb, and TCc are respectively attached to the front zones (62a, 64a), the middle zones (62b, 64b), and the rear zones (62c, 64c), and thermo couples TCL and TCR are respectively attached to the left and right side zones 66 and 68.

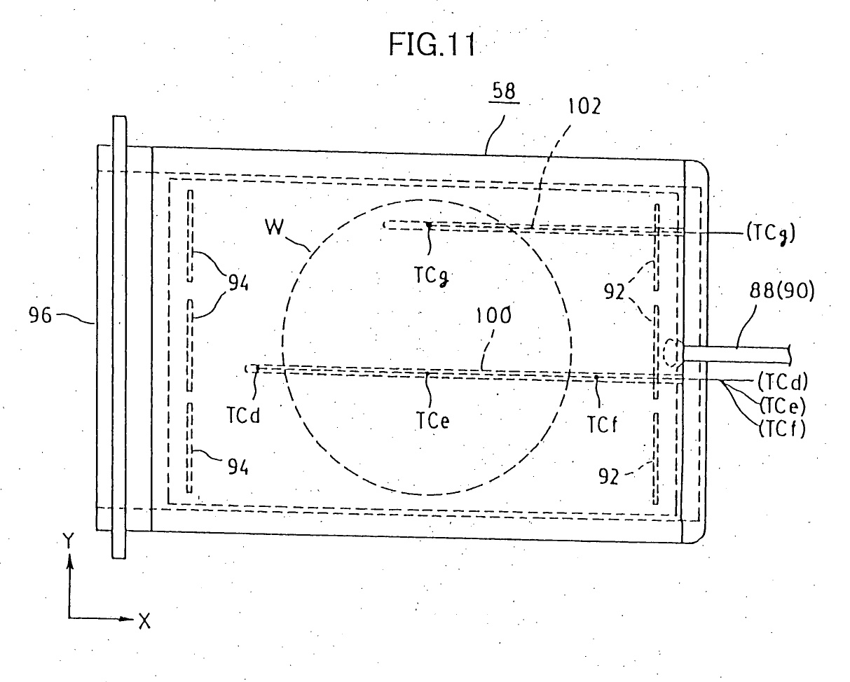

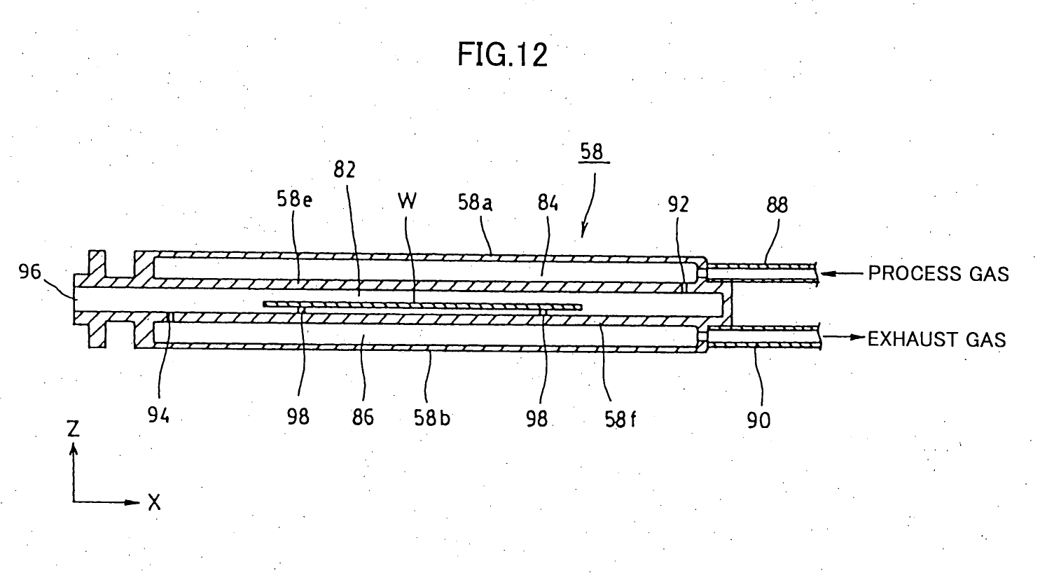

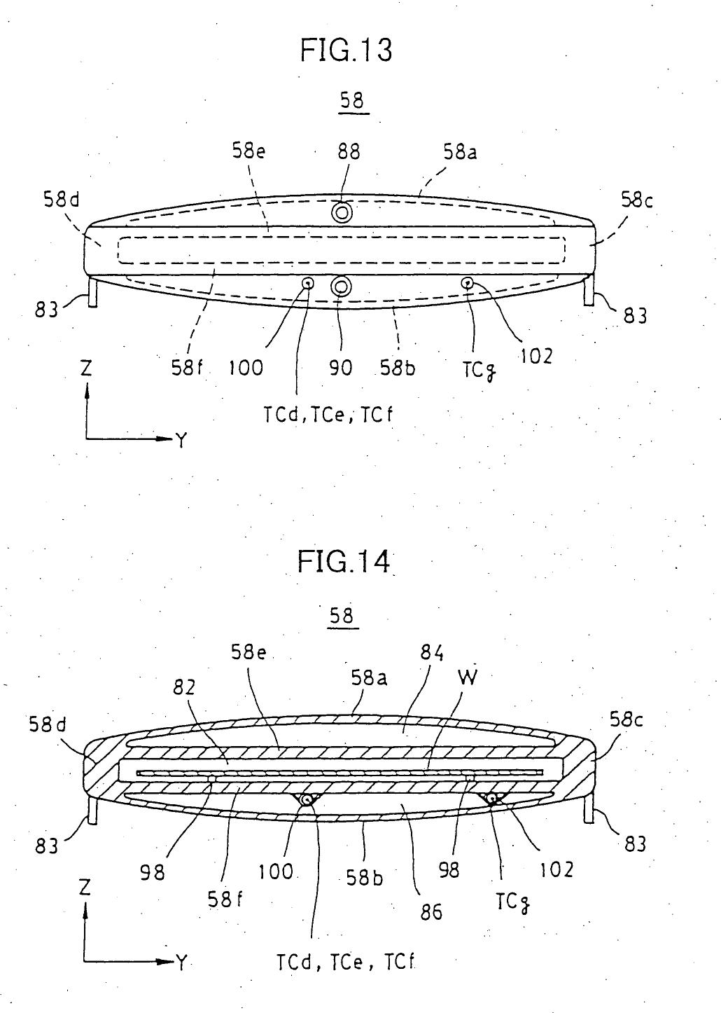

In FIGS. 8 and 9, a mouth (opening) 56a is formed on the front surface of the housing 56 (when viewed from the transfer chamber 40) for transporting the semiconductor wafer W in and out of the opening 56a. Further, formed on the rear surface of the housing 56 are: through holes 56a and 56c for allowing a process gas supply tube 88 and an exhaust tube 90 (described below, see FIGS. 11 through 13), being connected to the reaction tube 58, to penetrate therethrough; and through holes 56d and 56e for allowing each thermo couple TCd, TCe, TCf, TCg (see FIGS. 11, 12, 13, and 14), being attached to the reaction tube 58, to penetrate therethrough.

In the resistance heating device 60 of this embodiment, since uniformity of heat in the lateral direction (direction Y) is obtained by disposing the resistance heating portions 66, 68 to the left and right, respectively, of the top surface resistance heating portion 62 and the bottom surface resistance heating portion 64, the resistance heating elements disposed in each area 62, 64, 66, and 68 may be provided with the same standard or specification. Particularly, as in this embodiment, forming all of the coiled resistance heating elements RE with a uniform lead not only reduces manufacture costs, but also requires no adjustment between dense and sparse portions of the leads. Therefore, electrical control becomes easier. Nevertheless, according to necessity, the coiled resistance heating elements disposed in a desired zone may have a lead formed with a suitable denseness or sparseness.

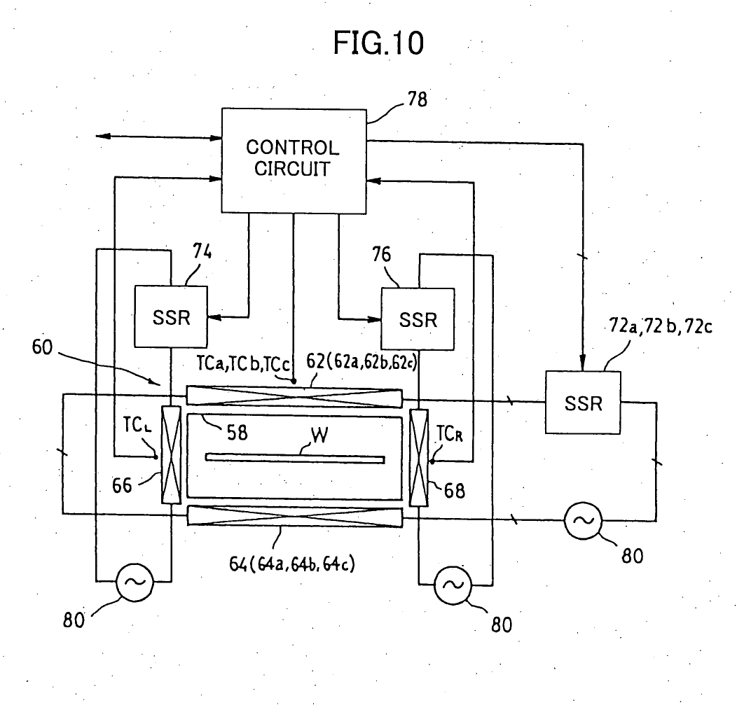

An exemplary structure of an electric control system of the resistance heating device 60 is shown in FIG. 10. In this embodiment, separate temperature adjustment switching circuits, such as SSR (Solid State Relay), 72a, 72b, 72c; 74; and 76 are provided to the front zones (62a, 64a), the middle zones (62b, 64b), the rear zones (62c, 64c); the left side zone 66; and the right side zone 68, respectively. Each SSR is switched on and off under the control of the control circuit 78 to thereby supply electricity to each zone from AC power source 80. The temperatures of the zones (62a, 64a), (62b, 64b), (62c, 64c), 66, and 68 are fed back via the thermo couples TCa, TCb, TCc, TCL, and TCR, respectively and each of the SSRs 72a, 72b, 72c, 74, and 76 is switched on and off for matching to respective predetermined values. Meanwhile, prescribed signals or data regarding electrical control of the resistance heating device 60 are exchanged between the control circuit 78 and a main controller (not shown).

As described above in this embodiment, the top surface resistance heating portion 62 and the bottom surface resistance heating portion 64 of the processing chamber 54 are divided, in the longitudinal direction (direction X), into three zones composed of the front zones (62a, 64a), the middle zones (62b, 64b), and the rear zones (62c, 64c). Nevertheless, the division may be executed in a given manner. The portions may be divided in half or into four or more zones, or divided in the lateral direction (direction Y). Further, according to necessity, the forming of either one of the top surface resistance heating portion 62 or the bottom surface resistance heating portion 64 may be omitted. The division of the left surface resistance heating portion 66 and the bottom surface resistance heating portion 64 may also be executed in a given manner.

In the aforementioned embodiment, a heating element having a carbon fiber sealed inside a quartz tube may be employed instead of the coiled resistance heating element. Such a heating element is disclosed in, for example, Japanese Patent Laid-Open Application No. 2000-21890, in which the heating element is formed by weaving plural bundles of bundled carbon fiber into wire-like or tape-like form, and enclosing the carbon fiber bundle in a sealed component made from quartz glass or aluminum. Non-oxide gas is guided into the space of the sealed component. By weaving the carbon fiber bundle, a shagged portion is formed in the carbon fiber bundle. By interposing the shagged portion between the wall of the carbon fiber and the sealed component, the sealed component can be prevented from being heated directly upon, and thereby, deterioration of the sealed component can be restrained.

FIGS. 11 through 14 show an embodiment of a structure of the reaction tube 58. The reaction tube 58 is entirely formed of a high heat resistant material such as quartz, and is shaped as a flat substantially rectangular solid. More specifically, a top outer wall portion 58a and a bottom outer wall portion 58b, both shaped as an arch, are formed between left-right wall portions 58c and 58d extending in a perpendicular direction. That is, the top outer wall portion 58a is shaped as an arch formed with an upward arc, and the bottom outer wall portion 58b is shaped as an arch form with a downward arc. A top inner wall portion 58e and a bottom inner wall portion 58f, each having a planar shape and extending in a horizontal direction, are formed on the inner side of the top outer wall portion 58a and the bottom outer wall portion 58b, respectively, for serving as a ceiling portion and a floor portion. The ceiling portion 58e, the floor portion 58f, and the left-right wall portions 58c, 58fd form a processing space or a processing chamber 82, which is shaped as a flat rectangular solid. A leg portion 83 is provided to each end portion of the left-right wall portions 58c and 58d.

A space 84 formed between the top outer wall portion 58a and the ceiling portion 58e and a space 86 formed between the bottom outer wall portion 58b and the floor portion 58f function as a buffer chamber for process gas or exhaust gas. The upper buffer chamber 84 is connected to the process gas supply tube 88, formed of, for example, a quartz tube, via a gas inlet formed on a rear surface of the reaction tube. The lower buffer chamber 86 is connected to the exhaust gas tube 90, formed of, for example, a quartz tube, via a gas outlet formed on a rear surface of the reaction tube. The process gas supply tube 88 communicates with a process gas supply portion (not shown), and the exhaust tube 90 communicates with an exhaust duct or a vacuum pump (not shown).

One or a plurality of vent holes or slits are formed in the ceiling portion 58e and the floor portion 58f for ventilating process gas and exhaust gas, respectively. In the illustrated exemplary structure, slits 92, extending in the lateral direction (direction Y), are formed in an end portion of the ceiling portion 58e toward the rear surface of the reaction tube, that is, a portion proximal to an outlet of the process gas supply tube 88. Further, slits 94, extending in the horizontal direction (direction Y), are formed in an opening of the floor portion 58f of the front side of the reaction tube, that is, a portion proximal to a wafer transport port 96 to which or from which wafers are transported.

With such a gas flow mechanism, the process gas, being supplied from the process gas supply tube 88 is first guided into the upper buffer chamber 84, is then guided into the reaction chamber 82 from the upper slits 92 situated toward the rear surface of the reaction chamber, and is then flowed toward the wafer transport port 96 in the reaction chamber 82. The exhaust gas in the reaction chamber 82 is drawn into the lower buffer chamber 86 from the lower slits 94 situated toward the wafer transport port 96, and is then, exhausted from the exhaust tube 90 via an exhaust port situated toward the rear surface of the reaction tube.

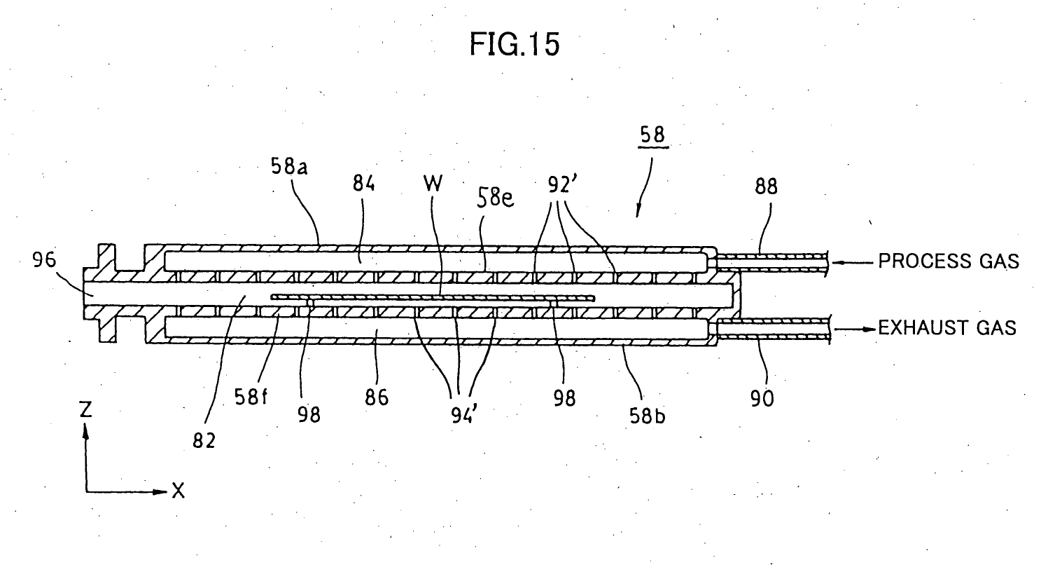

In a modified example, it is to be noted that numerous ventilation holes 92′, 94′ for ventilating process gas and exhaust gas may be formed at the ceiling portion 58e and the floor portion 58f in a broadly scattered manner as shown in FIG. 15. With such structure having numerous holes formed on a plane, process gas from the upper buffer chamber 84 can be uniformly applied to the semiconductor wafer W inside the processing chamber 82 in a shower-like manner. Further, the exhaust gas inside the processing chamber 82 can be exhausted uniformly and quickly through the entire floor portion 58f.

In the floor portion 58f of the processing chamber 82, a plurality of (e.g. three) projecting support portions 98 (e.g. formed of quartz) are separately arranged at prescribed positions for supporting the semiconductor wafer W more or less horizontally. The transport arm 42 inside the transport chamber 40 inserts the pincers 44 into the processing chamber 82 from the wafer transport port 96 so as to stack an unprocessed semiconductor wafer W on the projecting support portion 98 or to retrieve a processed semiconductor wafer W from the projecting support portion 98.

A temperature sensor that determines the temperature inside the processing chamber 82 as an approximate value may be attached to the upper buffer chamber 84 and/or the lower buffer chamber 86. In this embodiment, long and short quartz tubes 100 and 102 are inserted into the lower buffer chamber 86 from the rear surface of the reaction tube, and are attached (e.g. by welding) to the bottom surface of the floor portion 58f. One or a plurality of thermo couples TCd-TCg are inserted into the quartz tubes 100 and 102.

More specifically, the quartz tube 100, being situated in a position slightly deviating from the axial line in the lateral direction (that is, a position avoiding the gas tubes 88 and 90), is extended in direction X from the rear surface of the reaction tube to the proximity of the front portion of the reaction tube, in which three thermo couples TCd, TCe, and TCf having different length are inserted into the tube. The heat sensing portions (temperature measurement contact points) of the three thermo couples TCd, TCe, and TCf are situated at the front zones (62a, 64a), the middle zones (62b, 64b), and the rear zones (62c, 64c), respectively, of the resistance heating device 60, and are used for monitoring the effect of the radiant heat in the three zones in the longitudinal direction (direction X).

Further, the quartz tube 102, being situated on a left end portion or a right end portion of the processing chamber 82, is extended in direction X from the rear surface of the reaction tube to the proximity of the center portion of the reaction tube, in which one thermo couple TCg is inserted into the tube. The thermo couple TCg is used at the proximity of the wafer periphery in the lateral direction (direction Y) for monitoring the effect of the radiant heat from a side zone (in this embodiment, the left side zone 66). It is to be noted that a thermo couple may also be added for monitoring the effect of the radiant heat from the side zone disposed on the opposite side (the right side zone 68).

The output signals for each thermo couple TCd, TCe, TCf, and TCg may be sent to, for example, a main controller; then, according to necessity, may be sent from the main controller to the control circuit 78 of the resistance heating device 60 as feed back signals or adjustment signals. The reaction tube 58 in this embodiment, having a flat substantially rectangular solid shape, can be prevented from being damaged from stress created by inner and outer pressure difference, for example, where pressure in the reaction chamber of the reaction tube 58 is reduced. This is because the upper surface and the lower surface of the reaction tube 58 form a double layer structure, in which the double layer structure is created by forming the top outer wall portion 58a and the bottom outer wall portion 58b as arches between the left-right wall portions 58c, 58d, and forming the top inner wall portion 58e and the bottom inner wall portion 58f on the inner side of the top outer wall portion 58a and the bottom outer wall portion 58b as planar beam portions extending in a horizontal direction between the left-right wall portions 58c, 58d. In other words, although a considerable amount of force or stress is applied more to the upper and lower surfaces of the tube wall than the side surfaces of the tube wall in a case where pressure inside the reaction chamber of the reaction tube 58 is reduced, the double layer structure allows the stress to disperse between the top and bottom outer wall portions 58a, 58b and the top and bottom inner wall portions 58c, 58d, to thereby prevent breakage.

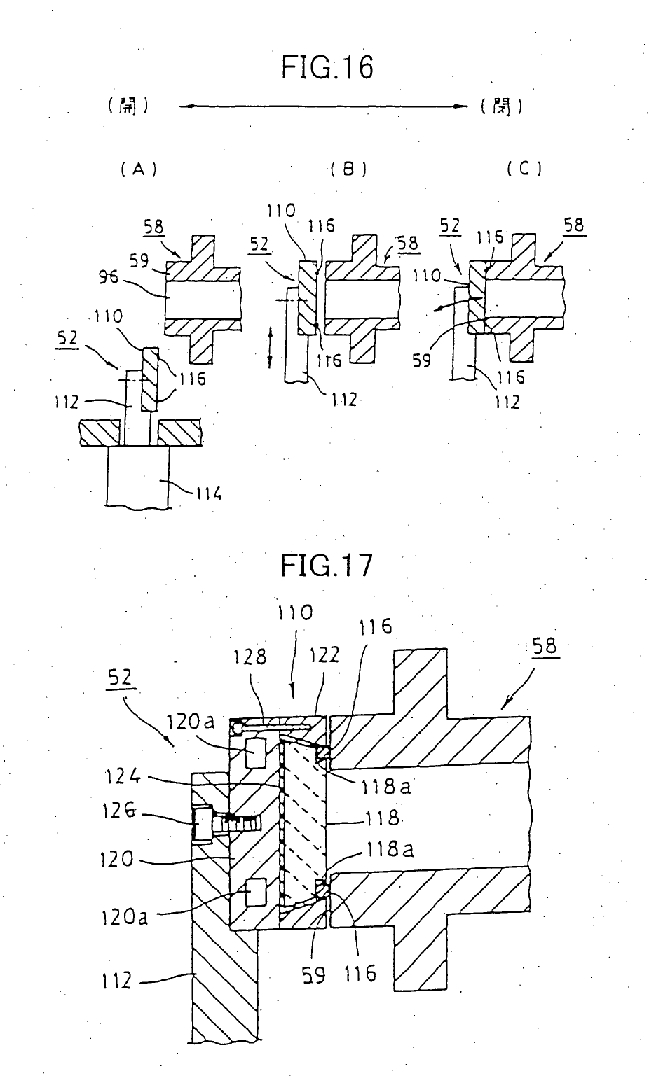

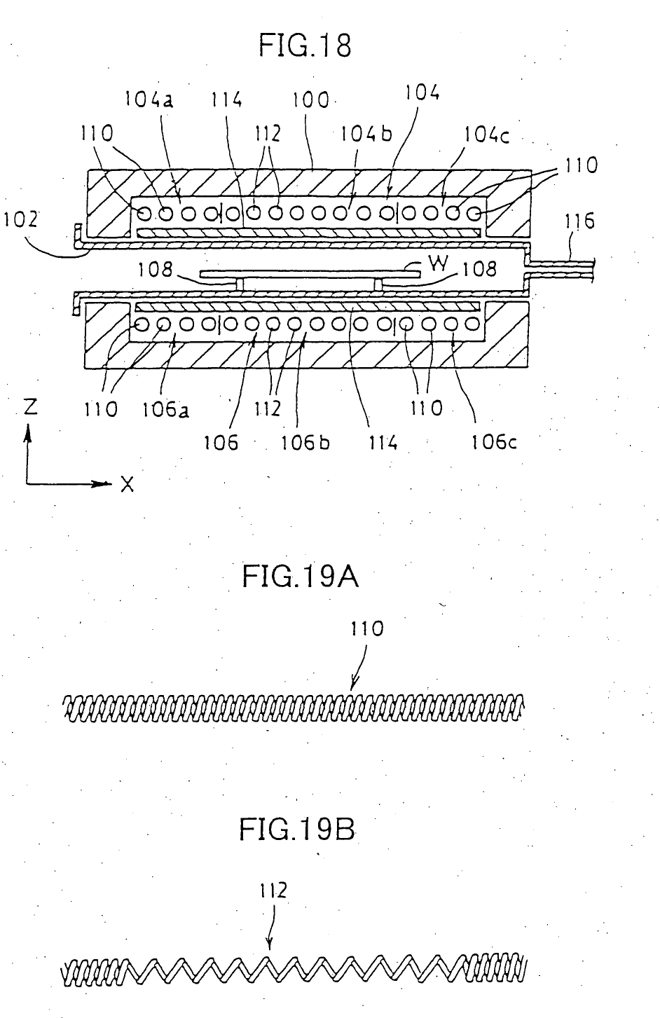

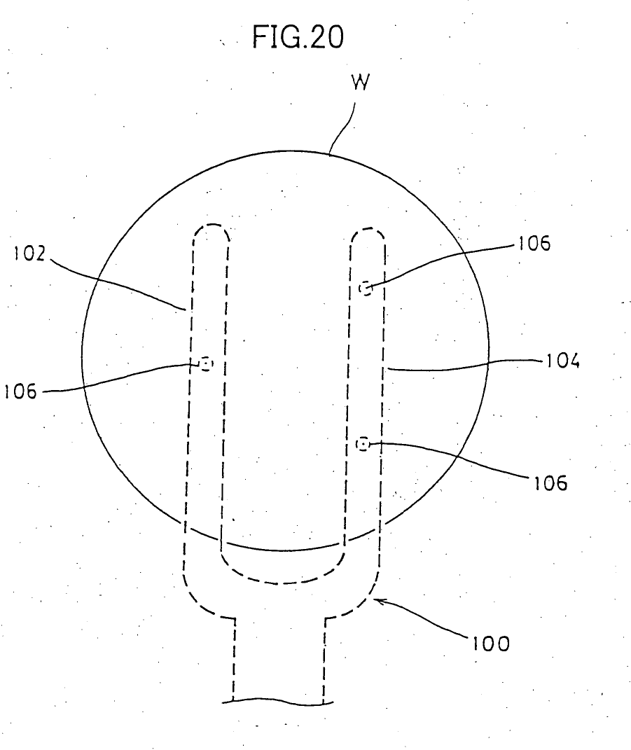

FIGS. 16 and 17 show a structure of the gate valve 52 provided to the wafer transport port 96 of the reaction tube 58 according to the present embodiment. As shown in FIG. 16, the gate valve 52 includes: a planar valve member 110 for opening and closing the wafer transport port 96 of the process tube 58; and a drive portion 114 which drives the valve member 110 to a closed position (FIG. 16 (C)) and to a retracted position (FIG. 16 (A)) via a rod-like support shaft or a drive shaft 112. A sealing member, for example, an O ring 116 is attached to an inner surface of the valve member 110 facing the wafer transport port 96. In the closed position (FIG. 16 (C)), the O ring 116 closely contacts and presses upon a front end surface 59 of the reaction tube 58 that serves as a valve seat thereof, thereby closing the wafer transport port 96 to form an air-tight state. The drive portion 114 having, for example, an air cylinder or a cam mechanism, moves the valve member 110 in an axial direction of the reaction tube 58 (longitudinal direction) when situated proximal to the wafer transport port 96, and moves the valve member 110 up and down in a perpendicular direction when situated away from the wafer transport port 96.

FIG. 17 shows an exemplary structure of the gate valve 52 of the valve member 110. The gate valve 52 of the valve member 110 includes: a planar base or a rear plate 120 engaged to the drive shaft 112; and a planar inner cover portion 118 fixed to an inner surface of the base 120 by a frame-like retaining member or a retainer 122. The base 120 and the retainer 122 are formed of a material with high thermal conductivity, for example, SUS; and the inner cover portion 118 is formed of quartz.

The outer peripheral surface of the inner cover portion 118 is formed as a tapered surface becoming narrower from the bottom surface (base) side to the top surface side. The inner peripheral surface of the retainer 122 is formed parallel to the outer peripheral surface of the inner cover portion 118, as a reverse tapered surface. Since the reverse tapered inner peripheral surface of the retainer 122 tightly covers the tapered outer peripheral surface of the inner cover portion 118, the inner cover portion 118 is pressingly fixed to the base 120. The retainer 122 is fixed to the base 120 by a bolt 128.

The base 120 is attached to the drive shaft 112 by a bolt 126. A passage 120a is provided inside the base 120 for passing a cooling medium (e.g. cooling water) therethrough. Cooling water from a cooling water supply portion (not shown) is circulated and supplied to the passage 120a via piping (not shown).

A sheet 124 (preferably of a white color), formed of a material of high thermal resistance and high reflectivity (e.g. polytetrafluoroethylene), is inserted between the inner cover portion 118 and the base 120/the retainer 122. A notch groove 118a is formed on a peripheral rim portion of the top surface (inner surface) of the inner cover portion 118 for receiving the O ring 116 therein. The O ring 116, having a portion protruding higher than the top surface (inner surface) of the inner cover portion 118, is retained between the groove 118a and the retainer 122. The color of the O ring 116 is a color having high reflectivity against radiant heat, preferably white or gray.

Thus structured, the inside portion of the reaction tube 58 is heated to a high temperature, for example, approximately 1100° C., and various process gases including corrosive gas are flowed therein. In this embodiment, since the inner cover portion 118 of the valve member 110, facing directly to the inside portion of the reaction tube 58, is formed of quartz, the inner cover portion 118 can provide high durability against the high temperature environment or the various process gases in the reaction tube 58; the semiconductor wafer W processed under high temperature inside the process tube 58 can be free from various kinds of contamination; and the wafer transport port 96 can be sealed safely.

Further, since the O ring 116 is of a color other than a black type color (preferably white or gray), the heat resistance of the O ring itself is enhanced. Further, the retainer 122, retaining the O ring 116 from the outer peripheral side, is able to efficiently release the heat proximal to the O ring 116 toward the base 120. Further, the inner cover portion 118, having its back turned against a cooling jacket type base 120, is able to provide an efficient cooling or heat releasing effect upon the O ring 116. With such cooling mechanism, the O ring 116 is able to steadily maintain a sealing function without being melted by the high temperature environment of the reaction tube 58.

The sheet 124 efficiently reflects the radiant heat from the reaction tube 58 and restrains the temperature of the valve member from rising. Further, the sheet 124 also prevents the base 120 and the inner cover portion (quartz) from directly contacting each other, to thereby prevent the strength of the inner cover portion 118 (quartz) from being reduced by such direct contact.

Next, the entire operation of the process apparatus according to this embodiment is described. As one example, rapid thermal processing such as oxidation, diffusion or the like is performed under high temperature (e.g. 1150° C.) in both processing chambers 54H, 54L of the process module 18. It is to be noted that the entire operation of the process apparatus described below is controlled by a main controller or a system controller.

A cassette CR having an unprocessed semiconductor wafer W housed therein or a cassette CR capable of housing a semiconductor wafer is transported into the cassette station 10, and then, the transported cassette CR is stacked on one of the cassette stacking bases 20. The wafer transport mechanism 22 of the loader/unloader section 12 is able to randomly access a cassette housing location in the cassette CR conveyed into the cassette station 10, and then, extract an unprocessed semiconductor wafer W from the cassette housing location.

The wafer transport mechanism 22 of the loader/unloader section 12 extracts a single unprocessed semiconductor wafer W, in a substantially horizontal state, from the cassette station 10, then turns the arm 26 approximately 180 degrees, then moves to the front of the alignment unit 38, and then, transports the semiconductor wafer W into the alignment unit 38. Inside the alignment unit 38, the semiconductor wafer W is subject to notch/orientation flat alignment and centering. After the completing of the positioning of the semiconductor wafer W, the wafer transport mechanism 22 conveys the semiconductor wafer W out from the alignment unit 38, then, moves the semiconductor wafer W, in direction Y, to the front of the load-lock chambers 28H, 28L of a multi-staged unprocessed substrate disposition portion, and then, elevationally moves the arm 26 to the height of one of the targeted load-lock chambers 28H, 28L, for example, to the height of the load-lock chamber 28H. The load-lock chamber 28H accepts the wafer transport mechanism having the open-close door 34, serving as a wafer entrance, in an opened state. The wafer transport mechanism 22 advances or extends the arm 26 into the load-lock chamber 28H, and carries the semiconductor wafer W onto the supporting pins 32 inside the chamber.

Then, the wafer transport mechanism 22 returns to the cassette station 10, and then extracts another unprocessed semiconductor wafer W from a random wafer housing location in a random cassette CR, and this time transports the semiconductor wafer W into the load-lock chamber 28L, in a similar manner as the foregoing procedure and operation. Accordingly, at separate timings, two unprocessed semiconductor wafers W, W ate transported into the load-lock chambers 28H, 28L, and both semiconductor wafers W, W are loaded in a manner disposed, in a horizontal state, as vertical two-stages. It is to be noted that the doors 34 of the wafer entrances in the load-lock chambers 28H, 28L are closed after the transport of the semiconductor wafers is completed, to thereby allow the pressure in the chambers to be reduced or allow the chambers to be switched into an inert gas environment according to necessity.

Meanwhile, in the process module 18, temperature control is executed in each processing chamber 54H, 54L with the resistance heating device 60 in order to maintain the temperature in the heating furnace (more precisely, temperature in the reaction tube 58) to a predetermined temperature (1150° C).

After or before the procedure where two semiconductor wafers W are received and disposed in the load-lock chambers 28H, 28L of the multi-staged unprocessed substrate disposition portion as vertical two-stages, the transport arm 42 is moved inside the transport chamber 40 of the transfet module 16, and both pincers 44H, 44L are disposed in front of the respective load-lock chambers 28H and 28L. When the gate valves 36, 36 situated toward the exit side of the load-lock chambers 28H, 28L are opened, the transport arm 42 advances/extends and inserts the pincers 44H, 44L into the load-lock chambers 28H, 28L, respectively, and then extracts the semiconductor wafers W, W, being in a vertical two-staged state, from the supporting pins 32, 32. Next, the transport arm 42 rotates through a prescribed angle while supporting the semiconductor wafers W, W with the pincers 44H, 44L, and then stands by after disposing the pincers 44H, 44L in front of the processing chambers 54H, 54L of the process module 18.

As shown in FIGS. 3-5, in each of the pincers 44H, 44L, the semiconductor wafer W is retained in a substantially horizontally placed state between the arm portions 48, 48 at a peripheral rim portion (excluded surrounding area) of its back side by two left-right pairs of claw portions 50 (total of 4 portions).

Then, when both gate valves 54, 54 are simultaneously opened in front of the processing chambers 54H, 54L, the transport arm 42 immediately transports the unprocessed semiconductor wafers W, W into the processing chambers 54H, 54L. More specifically, after the transport arm 42 inserts the pincers 44H, 44L into the reaction chamber 58, 58 and carries the unprocessed semiconductor wafers W onto the respective projecting support portions 98, 98, the transport arm 42 swiftly draws both pincers 44H, 44L out from the processing chambers 54H, 54L. Both gate valves 54, 54 are immediately closed thereafter.

In both processing chambers 54H, 54L, the unprocessed semiconductor wafers W, W, being transported into the reaction chambers 58, 58, are immediately placed under a predetermined temperature (1150° C.) and subjected to high temperature rapid thermal processing. It is to be noted that a procedure of supplying a prescribed process gas (in accordance with the process performed in the reaction chambers 58, 58) may be started in correspondence to the timing at which the wafers are transported thereto, for example, immediately after being transported thereto.

Meanwhile, both load-lock chambers 28H, 28L become empty when the unprocessed semiconductor wafers W are transported out from the load-lock chambers 28H, 28L of the multi-staged unprocessed substrate disposition portion to the transport chamber 40 in a vertical two-staged state. Then, the wafer transport mechanism 22 of the loader/unloader section 12, by finding a suitable timing, separately transports two unprocessed semiconductor wafers W, W in a random cassette CR in the cassette station 10 into the load-lock chambers 28H, 28L.

Both gate valves 54, 54, being situated toward the wafer entrance/exit, open simultaneously after a predetermined process time elapses from the time when the unprocessed semiconductor wafers W, W are transported into the processing chambers 54H, 54L. At this time, the transport arm 42 of the transfer module 16 is standing by in front of the processing chambers 54H, 54L. Accordingly, after the gate valves 54, 54 open simultaneously immediately after the completion of the thermal processing, the transport arm 42 immediately and thus simultaneously extracts the semiconductor wafers W, W, being in a high temperature state, from the processing chambers 54H, 54L. More specifically, after the transport arm 42 inserts both pincers 44H, 44L into both reaction chambers 58, 58 of the processing chambers 54H, 54L and extracts the processed semiconductor wafers W, W from the respective projecting support portions 98, 98, the transport arm 42 swiftly draws both pincers 44H, 44L out from the processing chambers 54H, 54L. Both gate valves 54, 54 may be immediately closed thereafter.

In the procedure of extracting the processed semiconductor wafer W from each processing chamber 54, the transport arm 42, being at a relatively low temperature (e.g. ordinary temperature), contacts the semiconductor wafer W, being in a high temperature state. In this embodiment, crystal defects such as slips may be prevented from being created in the semiconductor wafer W due to the transport arm 42 being in linear contact with the excluded surrounding area of the semiconductor wafer W at the claw portions 50 attached to both arm portions 48, 48 of the pincers 44.

In the transfer module 16, after the transport arm 42 transports the semiconductor wafers W, W out from the processing chambers 54H, 54L immediately after being subjected to the high temperature rapid thermal processing, the transport arm 42 rotates through a prescribed angle while supporting the semiconductor wafers W, W with the pincers 44H, 44L in the vertical two-staged state, and disposes the semiconductor wafers W, W into the load-lock chambers of a multi-staged unprocessed substrate disposition portion, that is, cooling chambers 30H, 30L. At this time, both gate valves 52, 52 may be in an open state toward the wafer entrance of the cooling chambers 30H, 30L.

Accordingly, the transport arm 42 can quickly insert the pincers 44H, 44L into the cooling chambers 30H, 30L, and then, stack the semiconductor wafers W, W, being in a high temperature state immediately after processing, onto the supporting pins 32 in the cooling chambers 30H, 30L. Once the pincers 44H, 44L are drawn out from the cooling chambers 30H, 30L, both gate valves 52, 52 are closed.

Accordingly, the semiconductor wafers W, W, which have been simultaneously placed under high temperature rapid thermal processing inside the processing chambers 54H, 54L, are simultaneously cooled to a prescribed temperature (e.g. ordinary temperature) inside the cooling chambers 30H, 30L medially disposed in a processed wafer transporting route between the transport chamber 40 and the cassette station 10.

Then, after the processed semiconductor wafers W, W are cooled in the cooling chambers 30H, 30L to a prescribed temperature, the wafer transport mechanism 22 of the loader/unloader section 12 accesses the cooling chambers 30H, 30L from the wafer exit side, and separately extracts the processed semiconductor wafers W, W therefrom.

The wafer transport mechanism 22, after extracting the processed semiconductor wafer W one by one from the cooling chambers 30H, 30L, rotates the transport arm 26 approximately 180 degrees, then moves the transport arm 26 in front of a desired cassette CR in the cassette station 10, and then inserts the processed semiconductor wafer W into a given wafer housing location in the cassette CR. Alignment of the processed semiconductor wafer W, where necessary, may be performed in the alignment unit 38 before the housing into the cassette CR.

Meanwhile, in the transfer module 16, after (preferably, immediately after) the transport arm 42 conveys the semiconductor wafers W, W into the cooling chambers 30H, 30L, the transport arm 42 is rotated through a prescribed angle and is disposed toward the load-lock chambers 28H, 28L of the multi-staged unprocessed substrate disposition portion in a state where the pincers 44H, 44L are empty (a state with no load). At this time, unprocessed semiconductor wafers W, W are newly disposed in the load-lock chambers 28H, 28L in a vertical two-staged state. Accordingly, when both gate valves 36, 36 are opened, the transport arm 42 places the semiconductor wafers W, W in a vertical two-staged state onto the pincers 44H, 44L and transports the semiconductor wafers W, W out from the load-lock chambers 28H, 28L to the processing chambers 54H, 54L.

The procedure of transporting unprocessed/processed semiconductor wafers W one by one between the cassette station 10 and the load-lock module 14 via the loader/unloader section 12, and the procedure of transporting unprocessed/processed semiconductor wafers W on a pair by pair basis and thus in a vertical two-staged state, between the load-lock module 14 and the process module 18 via the transfer module 16 are performed onwards in the same manner described above.

In the processing apparatus according to this embodiment, given that extraction or insertion of the semiconductor wafer W may performed one at a time in the cassette station 10, the wafer transport mechanism 22 of the loader/unloader section 12 may choose a random wafer installation position in a random cassette CR as an access target, and extraction and insertion of wafers may be performed quickly and accurately even where the interval of the wafer installation positions in the cassette CR is relatively narrow. Further, given that the alignment unit 38 may be formed with an alignment mechanism for a single wafer, the alignment unit 38 may be downsized and may be easier to access for the wafer transport mechanism 22. Nevertheless, it is possible to form the alignment unit 38 having an alignment mechanism with multiple stages for simultaneously aligning plural semiconductor wafers W.

Further, owing that the wafer transport mechanism 22 can transport the semiconductor wafers W in and out from the load-lock module 14 one at a time, the wafer transport mechanism 22 can flexibly access each of the load-lock chambers at a different timing, and transport the wafers W.

Meanwhile, the transport arm 42 of the transfer module 16 can efficiently and accurately perform simultaneous single wafer processing on a plurality of semiconductor wafers W by supporting and transporting multi-staged unprocessed/processed semiconductor wafers W inside the transport chamber 40 directly connected to the process module 18.

Especially, according to this embodiment, since the two unprocessed/processed semiconductor wafers W, W are transported in and out with a pair of vertical two-staged pincers 44H, 44L while the inside of the vertical two-staged reaction chambers 58, 58 of the processing chambers 54H, 54L in the process module 18 is kept at a high temperature for thermal processing, the surface targeted for high temperature rapid thermal processing can be heated or cooled more rapidly.

Furthermore, in the load-lock module 14 of the processing apparatus, load-lock chambers 28H, 28L for disposing and loading unprocessed semiconductor wafers W on multiple stages and load-lock chambers 30H, 30L for disposing and loading processed semiconductor wafers W on multiple stages are arranged in parallel. Thus structured, the operation for transporting unprocessed substrates and the operation for transporting processed substrates can be performed in parallel or simultaneously, to thereby increase throughput.

Furthermore, the load-lock chambers 30H, 30L of the multi-staged processed substrate disposition portion are used as cooling chambers, in which both semiconductor wafers W, W, after being subject to high temperature rapid thermal processing inside the processing chambers 54H, 54L, are set loaded inside the cooling chambers 30H, 30L medially disposed in the processed wafer transporting route between the transport chamber 40 and the cassette station 10 so as to be cooled to a prescribed temperature. Accordingly, a dedicated cooling chamber requiring a particular occupation space is unnecessary, thereby reducing the cost of the apparatus as well as the foot print thereof.

In the reaction tube 58 of the processing chamber 54 according to the above described embodiment, a tube structure, formed as thin as possible with large pressure resistance, can be obtained by forming the top outer wall portion 58a and the bottom outer wall portion 58b each into an arch shape. The top outer wall portion 58a and/or the bottom outer wall portion 58b may, however, be formed into shapes other than an arch (e.g. planar shape). Although the top outer wall portion 58a and the bottom outer wall portion 58b in the present embodiment respectively form an arch between the left-right wall portions 58c, 58d, the arch may be formed between the front surface of the tube and the rear surface of the tube.

In the above described embodiment, various modifications may be made to the form or materials, for example, of the components of the transport arm 42 of the transfer module 16. For example, the total number of the claw portions (both left and right) may be three or five or more. Although it is preferable to form the top surface of the claw portion 50 as downward sloped plane having a protruding planar roundness, the top surface may, for example, be formed as a straight downward sloped plane without having any roundness, or as a horizontal plane. The arm portion 48 is not required to be formed as a straight tubular shape, but may formed with a curved shape, or with a solid structure.

In the processing chamber 54 of the above described embodiment, the top surface resistance heating portion 62 and the bottom surface resistance heating portion 64 are each divided into three portions in the longitudinal direction (direction X) comprising the front zone 62a, 64a, the middle zone 62b, 64b, and the rear zone 62c, 64c. Nevertheless, the division of the zones may be performed in a given manner, in which the zones may be divided in half or into four portions or more, or the zones may be divided in a lateral direction (direction Y). Further, according to necessity, one of either the top surface resistance heating portion 62 or the bottom surface resistance heating portion 64 may be omitted from the structure. Further, the left surface resistance heating portion 66 and the bottom surface resistance heating portion 64 may also be divided in a given manner.

Further, in the process module 18 of the above described embodiment, the processing chambers 54H, 54L are structured as chambers for rapid thermal processing. Nevertheless, the processing chambers 54H, 54L may be structured for other processes, for example, chambers for plasma processing or etching.

The processing method according to the present invention may be applied to processing in ordinary pressure, in reduced pressure, or in a vacuum. The subject substrate is not limited to a semiconductor wafer, but may be, for example, an LCD substrate, a glass substrate, a CD substrate, a photomask, or a printed circuit board.

The present invention is not limited to the embodiments described above in detail, and can be subjected to various changes and modifications within the scope of the present invention.

1. A processing apparatus comprising:
a station for housing a plurality of substrates in a substrate transport container;
a processing section at which a plurality of processing chambers are provided in multi-stages for applying a prescribed process to the respective substrates inside a hermetically sealable chamber by using a prescribed process gas;
a multi-staged substrate disposition section for temporarily loading the substrates being disposed in a plural multi-staged state, between the station and the processing portion;
a first transport part for transporting the substrates one by one between the station and the multi-staged substrate disposition portion; and
a second transport part for transporting a plurality of the substrates, being supported in a multi-staged state, simultaneously between the multi-staged substrate disposition portion and the processing portion.

2. The processing apparatus as claimed in claim 1, wherein a thermal processing part is provided for thermally processing the substrates inside each of the processing chambers.

3. The processing apparatus as claimed in claim 2, wherein the thermal processing part includes a rapid heating part for thermally processing the substrates in a short time.

4. The processing apparatus as claimed in claim 1, wherein the multi-staged substrate disposition section comprises a plurality of load-lock chambers receiving the substrates one by one.

5. The processing apparatus as claimed in claim 4, wherein the second transport part is provided inside a transport chamber that is connected to all of the load-lock chambers of the multi-staged substrate disposition section, and also connected to all of the processing chambers of the processing section.

6. The processing apparatus as claimed in claim 4, wherein the multi-staged substrate disposition section includes: a multi-staged unprocessed substrate disposition portion for temporarily loading a plurality of the substrates being disposed in a multi-staged state, prior to being processed at the processing section; and a multi-staged processed substrate disposition portion for temporarily loading the plurality of substrates being disposed in a multi-staged state, subsequent to being processed at the processing section.

7. The processing apparatus as claimed in claim 6, wherein the multi-staged processed substrate disposition portion comprises a cooling mechanism for cooling the substrates to a prescribed temperature.

8. The processing apparatus as claimed in claim 2, wherein the thermal processing part comprises:
a reaction tube in which the substrate is received and disposed at a prescribed position;
a first resistance heating portion being structured as a planar shape, and facing substantially in parallel to the substrate received in the reaction tube; and
a second resistance heating portion being structured as a planar shape at a periphery of the substrate received in the reaction tube, and perpendicularly intersecting with the first resistance heating portion.

9. The processing apparatus as claimed in claim 8, wherein the first resistance heating portion is divided into a plurality of zones, and performs resistance heating by being electrically controlled in each of the zones.

10. The processing apparatus as claimed in claim 9, wherein the second resistance heating portion performs resistance heating by being electrically controlled independently from each zone of the first resistance heating portion.

11. The processing apparatus as claimed in claim 8 or claim 9, wherein the second resistance heating portion, being disposed at the left and right of the substrate as a pair, performs resistance heating by being electrically controlled independently from each other.

12. The processing apparatus as claimed in claim 8, wherein the first/second resistance heating portions are heating members using a heater enclosing a carbon fiber, which is braided into a net, inside a sealing member.

13. The processing apparatus as claimed in claim 12, wherein the sealing member is formed of quartz glass or alumina.

14. The processing apparatus as claimed in claim 1, wherein the second transport part comprises:
a pair of arm portions being spaced with an interval greater than the width of the substrate, and facing substantially horizontally to each other; and
a plurality of retaining portions being provided to the pair of arm portions at prescribed intervals, and being in contact with a peripheral portion of the substrate for retaining the substrate.

15. The processing apparatus as claimed in claim 14, wherein the retaining portion comprises a top surface sloped downward from a proximal end portion toward the arm portion to a distal end portion.

16. The processing apparatus as claimed in claim 15, wherein the top surface of the retaining portion has a protruding planar roundness.

17. The processing apparatus as claimed in claim 14, wherein the arm portion and the retaining portion are formed of quartz.

18. A processing method comprising:
a first step placing a plurality of unprocessed substrates in a prescribed station;
a second step separately transporting a plurality of unprocessed substrates from the station to a plurality of substrate placement areas being set in multi-stages;
a third step temporarily loading a plurality of unprocessed substrates on the multi-staged substrate placement area;
a fourth step simultaneously transporting a plurality of unprocessed substrates from the multi-staged substrate placement area to a plurality of chambers being disposed in multi-stages;
a fifth step simultaneously applying a prescribed process to the plurality of substrates inside each of the plurality of chambers by using a prescribed process gas;
a sixth step simultaneously extracting and transporting a plurality of processed substrates from the plurality of chambers to the multi-staged substrate placement area;
a seventh step temporarily loading a plurality of processed substrates on the multi-staged substrate placement area; and
an eighth step separately transporting a plurality of processed substrates from the multi-staged substrate placement area to the station.

19. The processing method as claimed in claim 18, wherein the substrates are simultaneously thermally processed in the plurality of chambers in the fifth step.

20. The processing method as claimed in claim 18, wherein a plurality of sets of the multi-staged substrate placement area are provided, wherein one set of unprocessed substrates is loaded on a first set of the multi-staged substrate placement area while another set of processed substrates is loaded on a second set of the multi-staged substrate placement area.

21. The processing method as claimed in claim 18, wherein a plurality of the processed substrates are cooled to a prescribed temperature in the second set of the multi-staged substrate placement area.

22. A thermal processing method comprising:
a first step keeping the inside of a reaction tube at a predetermined temperature;
a second step transporting a substrate into the reaction tube under the predetermined temperature by using a substrate transport apparatus which retains and transports the substrate in a substantially horizontal state, the substrate transport apparatus having a pair of arm portions being spaced with an interval greater than the width of the substrate, and facing substantially horizontally to each other, and a plurality of retaining portions being provided to the pair of arm portions at prescribed intervals, and being in contact with a peripheral portion of the substrate for retaining the substrate;
a third step applying a prescribed thermal process to a targeted process surface of the substrate by supplying a prescribed process gas to the reaction tube while exhausting the inside of the reaction tube;
a fourth step withdrawing the substrate from the reaction tube with the substrate transport apparatus after a predetermined process time has elapsed; and
a fifth step cooling the withdrawn substrate to a prescribed temperature at a cooling portion set outside of the reaction tube.

23. The thermal processing method as claimed in claim 22, wherein the inside of the reaction tube is maintained at the predetermined temperature from beginning to end in the third step.

24. A thermal processing apparatus comprising:
a reaction tube in which a substrate is received and disposed at a prescribed position;
a first resistance heating portion being structured as a planar shape, and facing substantially in parallel to the substrate received in the reaction tube;
a second resistance heating portion being structured as a planar shape at a periphery of the substrate received in the reaction tube, and perpendicularly-intersecting with the first resistance heating portion;
a heat spreading member being provided between the reaction tube and the first/second resistance heating portions so that the heat created in the first/second resistance heating portions is uniformly spread inside the reaction tube; and
a heat insulating member being provided to surround the first/second resistance heating portions.

25. The thermal processing apparatus as claimed in claim 24, further comprising a temperature detection unit for feeding back the temperature in each zone of the first/second resistance heating portions to an electric control for each zone.

26. A substrate transport apparatus transporting a substrate while retaining the substrate horizontally, the substrate transport apparatus comprising:
a pair of arm portions being spaced with an interval greater than the width of the substrate, and extending in parallel to each other; and
a plurality of retaining members being attached to each of the pair of arm portions in a manner extending from one to the other of the pair of the arm portions, characterized in that the plurality of retaining members contacts a peripheral portion of a back side of the substrate to retain the substrate horizontally.

27. A thermal processing apparatus comprising:
a reaction tube in which a substrate is received and disposed at a prescribed position;
a first resistance heating portion being structured as a planar shape, and facing substantially in parallel to the substrate received in the reaction tube;
a second resistance heating portion being structured as a planar shape at a periphery of the substrate received in the reaction tube, and perpendicularly intersecting with the first resistance heating portion;
a heat spreading member being provided inside the reaction tube so that the heat created in the first/second resistance heating portions is uniformly spread in the inside of the reaction tube; and
a heat insulating member being provided to surround the first/second resistance heating portions.

28. The thermal processing apparatus as claimed in claim 27, further comprising a temperature detection unit for feeding back the temperature in each zone of the first/second resistance heating portions to an electric control for each zone.

29. A thermal processing apparatus comprising:
a reaction tube in which a substrate is received and disposed at a prescribed position;
a first resistance heating portion being structured as a planar shape, and facing substantially in parallel to the substrate received in the reaction tube;
a second resistance heating portion being structured as a planar shape at a periphery of the substrate received in the reaction tube, and perpendicularly intersecting with the first resistance heating portion; and
a heat insulating member being provided to surround the first/second resistance heating portions.

30. The thermal processing apparatus as claimed in claim 27, further comprising a temperature detection unit for feeding back the temperature in each zone of the first/second resistance heating portions to an electric control for each zone.
